(19) United States
(12) Patent Application Publication
(10) Pub. No.: US 2026/0132498 A1
(43) Pub. Date: May 14, 2026

(54) SYNTHETIC BROCHOSOMES FOR INFRARED SIGNATURE MANAGEMENT

(71) Applicants: THE PENN STATE RESEARCH FOUNDATION, University Park, PA (US); Carnegie Mellon University, Pittsburgh, PA (US)

(72) Inventors: Tak Sing WONG, University Park, PA (US); Lin WANG, University Park, PA (US); Sheng SHEN, Pittsburgh, PA (US); Zhuo LI, Pittsburgh, PA (US)

(21) Appl. No.: 18/940,349

(22) Filed: Nov. 7, 2024

Related U.S. Application Data
(60) Provisional application No. 63/596,790, filed on Nov. 7, 2023.

(51) Int. Cl. C23C 14/02; C23C 14/16; C23C 14/30; C23C 14/34; G03F 7/027

(52) U.S. Cl. CPC C23C 14/024; C23C 14/16; C23C 14/30; C23C 14/34; G03F 7/027

(57) ABSTRACT

Natural brochosomes are hollow, nanoscopic, buckyball-shaped spheroids with through-holes distributed across their surfaces. Synthetic brochosomes can be prepared utilizing a microscopic three-dimensional printing method. The printed structures possess spherical, hemispherical, buckyball-like geometries. And the secondary features on these printed synthetic brochosomes are either in a shape of circular or a shape of hexagon and pentagon. The secondary feature can be open-pores or closed-pores. The brochosome can be made with polymers or comprised of composite materials including polymers and metals. These synthetic brochosomes can be used as antireflective coatings, optical encryption, and camouflage coatings in the infrared range from 750 nm to over 20 μm.

### CROSS REFERENCE TO RELATED APPLICATIONS

This application claims the benefit of priority to U.S. Provisional Application No. 63/596,790, filed Nov. 7, 2023, which is incorporated by reference herein in its entirety.

### GOVERNMENT SUPPORT CLAUSE

This invention was made with government support under Grant Nos. N00014-20-1-2095, N00014-21-1-2337 and N00014-23-1-2173 awarded by the United States Navy/ONR. The Government has certain rights in the invention.

### TECHNICAL FIELD

The present disclosure relates to the use of synthetic brochosomes for infrared signature management including antireflection and thermal emission control in the infrared range.

### BACKGROUND

Considered as one of the most sophisticated natural structures, brochosomes are three-dimensional, soccer ball-like granules with distributed nanoscale cavities produced by leafhoppers (M. F. Day et al., “The Origin and Structure of Brochosomes,”, J Ultra Mol Struct R, vol. 2, pp. 239-244, 1958) (R. Rakitov et al., “Brochosomal coats turn leafhopper (Insecta, Hemiptera, Cicadellidae) integument to superhydrophobic state,”, P Roy Soc B-Biol Sci, vol. 280, p. 20122391, 2013). Owing to the highly sophisticated geometry and the micro- and nanoscale dimensions of the natural brochosomes, creating the synthetic version of brochosomes has been a technological challenge even with the state-of-the-art micro- and nanofabrication technologies. The first “synthetic brochosomes” was demonstrated in 2017, in which these synthetic brochosomes were fabricated using double-layer colloidal assembly and electro-deposition methods at the centimeter scale (S. Yang et al., Ultra-antireflective synthetic brochosomes, Nature Communications 8: 1285, 2017) (T. S. Wong et al., “Antireflective Synthetic Brochosomal Coatings,” U.S. Ser. No. 10/890,690 B2) (T. S. Wong et al., “Antireflective Synthetic Brochosomal Coatings,” US 2021/0181380 A1). Brochosome particles of diameters ranging from 1 μm to 4.5 μm and non-through-hole pore sizes ranging from 200 nm to 1 μm have been fabricated. Specifically, the synthetic brochosomes have shown to maintain ultralow reflectance of <1.5% from UV, visible, and near-infrared (IR) range (i.e., 250 nm-2 μm) with omnidirectionality of up to θ>65°. Since the first demonstration, a number of research groups in the world have utilized modified colloidal assembly and cast-molding methods to create synthetic brochosome coatings at the centimeter scale range (C. Hua et al., “Enhanced Electrochromic Tungsten Oxide by Bio-Inspired Brochosomes.” J. Electrochem. Soc., vol. 168, pp. 042503, 2021) (C.-W. Lei et al., “Leafhopper Wing-Inspired Broadband Omnidirectional Antireflective Embroidered Ball-Like Structure Arrays Using a Nonlithography-Based Methodology.” Langmuir, vol. 36, pp. 5296-5302, 2020) (P.-C. Li et al., “Reversible embroidered ball-like antireflective structure arrays inspired by leafhopper wings.” J. Colloid Interf. Sci. vol. 599, pp. 119-129, 2021).

However, it is important to note that the aforementioned micro- and nanofabrication methods are only able to mimic part of the topographical features of natural brochosomes and are not able to fully emulate the full geometrical features of the natural brochosomes. Specifically, natural brochosomes contain interconnected through-holes with hollow cores, in which these geometrical features cannot be replicated by the aforementioned fabrication methods. As such, there is a need for manufacturing synthetic brochosomes that emulate the complex hollow geometries of natural brochosomes and said brochosomes themselves. These needs and others are at least partially satisfied by the present disclosure.

### SUMMARY

The present disclosure relates to synthetic brochosomes prepared utilizing a microscopic three-dimensional printing method. The printed structures can possess spherical, hemispherical, buckyball-like geometries. The secondary features on these printed synthetic brochosomes can be either circular, hexagonal, and/or pentagonal. The secondary feature can be open-pores or closed-pores. The brochosome can be made with polymers or comprised of composite materials including polymers and metals. These synthetic brochosomes can be used as antireflective coatings, optical encryption, and camouflage coatings in the infrared range from 750 nm to over 20 μm.

These synthetic brochosomes can be used as 1) particles assembled on a solid surface, 2) particles embedded within a solid medium, or as 3) particles suspended in fluid medium. These uses include, without limitation, (1) liquid-repellent coating, (2) antireflection coating, (3) particle scatterers and absorbers for optical signal management particularly in the infrared range, and (4) thermal signature management.

In an aspect, provided is a method of forming a synthetic brochosome, comprising: irradiating a portion of a photoresist coated onto a substrate with a focused radiation beam or light sheet, wherein the beam or light sheet is moved along a designated pathway within the photoresist to polymerize the portion of the photoresist irradiated by the beam or light sheet; and removing a portion of the photoresist from the substrate that is not irradiated and not polymerized by the beam or light sheet, thereby providing a synthetic brochosome.

In another aspect, provided is a synthetic brochosome comprising a photoresist having a conductive coating.

In another aspect, provided is a coated substrate comprising a coating of any of the disclosed synthetic brochosomes disposed on a substrate.

Other systems, methods, features and/or advantages will be or may become apparent to one with skill in the art upon examination of the following drawings and detailed description. It is intended that all such additional systems, methods, features and/or advantages be included within this description and be protected by the accompanying claims.

### BRIEF DESCRIPTION OF DRAWINGS

FIG. 1 depicts synthetic brochosomes in different form factors. Six different exemplary designs were designed and fabricated: buckyball-like brochosomes with and without through-holes, hemispherical brochosomes with and without through-holes, and spherical brochosomes with and without through-holes.

FIG. 2 depicts a schematic illustration of two-photon polymerization 3D printing. The designed 3D structures as illustrated in FIG. 1 were translated to a substrate (a silicon wafer was used in this disclosure) by utilizing a 780 nm femtosecond laser beam.

FIGS. 3A-3F depict scanning electron microscope (SEM) images of 3D printed synthetic brochosomes in different form factors. The material used for the 3D printing is a polymer called IP-DIP and each brochosome was coated with a nickel layer. The overall diameter of each brochosome is ˜20 μm. The geometry of these synthetic brochosomes includes buckyball-like brochosome with through-holes (FIG. 3A); buckyball-like brochosomes without through-holes (FIG. 3B); hemispherical brochosomes with through-holes (FIG. 3C); hemispherical brochosomes without through-holes (FIG. 3D); spherical brochosomes with through-holes (FIG. 3E); and spherical brochosomes without through-holes (FIG. 3F).

FIGS. 4A-4C depict SEM images of 3D printed spherical synthetic brochosomes with through-holes in a square lattice. The diameter is about 20 μm and the edge-to-edge gap is about 4 μm.

FIGS. 5A-5B depict experimentally measured specular reflectance of a buckyball-like synthetic brochosome array as a function of wavelength. The reflectance in the range of 2.5 μm to 10 μm (FIG. 5A) and 10 μm to 24 μm (FIG. 5B).

FIGS. 6A-6B depict specular infrared reflectance comparison between hemispherical synthetic brochosome with and without through-holes. FIG. 6A depicts specular infrared reflectance data showing the comparison between nickel mirror (a 100-nm nickel layer coated flat silicon wafer), nickel-coated hemispherical synthetic brochosomes with and without through-holes. The diameter of the brochosome is ˜20 μm with the through-hole diameter of ˜3.7 μm. The brochosomes were coated with Ni of ˜100 nm. The nickel-coated brochosomes with through-holes show a reduced reflectance in the range of 2.5 μm to 6 μm compared to those without through holes. FIG. 6B shows infrared reflectance reduction on synthetic brochosomes with and without through-holes as compared to a flat nickel mirror.

FIG. 7 depicts reflectance of nickel coated spherical brochosome with through-holes compared with the reflectance of a flat nickel mirror. The brochosomes were arranged in a square lattice with a diameter of about 20 μm and an edge-to-edge distance of about 4 μm.

FIGS. 8A-8D depicts infrared reflectance comparison between spherical synthetic brochosomes with through-holes coated with different metals. The measured infrared reflectance data showing that the reflectance spectra on a series of spherical brochosome arrays are consistently reduced to approximately 10% to 20% in the range of 2.5 μm to 17 μm regardless the various highly reflective metal coatings on these brochosomes, demonstrating that the anti-reflection capability of brochosome-like structures is materials independent. The brochosomes were arranged in a square lattice with a diameter of about 20 μm and an edge-to-edge distance of about 4 μm.

FIG. 9 depicts infrared reflectance comparison between buckyball-like synthetic brochosomes with through-holes in different arrangements. The measured infrared specular reflectance data show that random, square, hexagon arrangements exhibit similar anti-reflection capability in the 2.5 μm to 17 μm range.

FIG. 10 depicts infrared reflectance comparison between hemispherical synthetic brochosomes in hexagon arrangements with different edge-to-edge gap distance. By adjusting the gap distance as 0 μm, 10 μm, or 20 μm, the specular reflectance of the synthetic brochosome arrays can be increased from about 10%, to about 40%, to about 70%, respectively.

FIGS. 11A-11H depict camouflage and display by spherical synthetic brochosome arrays showing letters ‘C’ and ‘P’, and a quick-response code (QR code). FIG. 11A and FIG. 11E show SEM images of brochosome arrays patterned to encrypt letters ‘C’ and ‘P’ (to manifest the collaboration between Carnegie Mellon University and the Pennsylvania State University) and a QR code (storing the address of the homepage of Carnegie Mellon University), respectively. FIG. 11B and FIG. 11F show optical images of the BLP arrays. The encrypted information is invisible in the visible light range. FIG. 11C and FIG. 11G show infrared images of the BLP arrays taken by thermal mapping, revealing the encrypted information. FIG. 11D and FIG. 11H show calculated spatial distribution of emissivity based on the infrared images, showing the contrast between the encrypted patterns and the background. Scalebar: top row 100 μm, bottom row 150 μm.

FIGS. 12A-12F depict the leafhopper and its brochosomes. FIG. 12A shows an optical image of a leafhopper Gyponana serpenta. FIG. 12B shows a scanning electron microscopy (SEM) image of the leafhopper wing (highlighted area in FIG. 12A). FIGS. 12C-12D show SEM images of brochosomes on the leafhopper wing, revealing their hollow buckyball-like geometry. FIG. 12E shows an SEM image showing the cross-section of a natural brochosome cleaved by the focused ion beam (FIB) technique. FIG. 12F shows the relationship between the diameter of brochosome through-holes and the diameter of brochosomes across different leafhopper species. Brochosome diameter and hole diameter were determined from experimental measurements and a literature source (18). The fitted dashed line indicates that the through-hole diameters are approximately 28% of the corresponding brochosome diameters.

FIGS. 13A-13C depict the monodispersity of natural brochosomes. FIG. 13A shows a SEM image showing the monodisperse natural brochosomes on leafhopper wings. FIG. 13B shows diameter distribution of brochosomes. The average diameter of brochosomes is around 661±47 nm. Approximately 81% of natural brochosomes have a diameter in the range of 600 nm to 720 nm. FIG. 13C shows through-hole size distribution in natural brochosomes. The average diameter of through-holes is around 193±22 nm. Approximately, 79% of the though-holes have a diameter in the range of 160 nm to 220 nm.

FIGS. 14A-14G depict high-fidelity 3D-printed synthetic brochosomes. FIG. 14A shows an SEM image showing an array of HCP synthetic brochosomes covering an area of approximately 400 μm by 350 μm. The brochosome diameter is around 20 μm with a through-hole diameter of approximately 5 μm. FIGS. 14B-14C show synthetic brochosomes with through-holes. FIG. 14D shows an SEM image revealing the cross-section and internal geometry of a synthetic brochosome. Specifically, the through-holes are interconnected via a cavity at the brochosome center, closely mimicking the structure of natural brochosomes. FIGS. 14E-14G show SEM images illustrating the synthetic brochosomes without through-holes and their corresponding cross-sections.

FIGS. 15A-15C depict design parameters of synthetic brochosomes. FIG. 15A shows a scanning electron microscopy (SEM) image of a 3D printed synthetic brochosome showcasing the diameter of through-holes. FIG. 15B shows a schematic illustration of a brochosome with diameter, D. FIG. 15C shows a schematic illustration of the cross section of a brochosome with shell thickness, s, and through-hole wall thickness, t.

FIGS. 16A-16H depict Mie scattering and through-hole absorption effect on brochosome arrays. FIG. 16A shows a schematic illustration depicting Mie scattering on a brochosome when the wavelength of light, λ, is comparable to the diameter of brochosome, D. FIG. 16B shows experimentally measured specular reflectance of a synthetic brochosome array as a function of λ/D. Insets display SEM images showing individual synthetic brochosomes with and without through-holes. (Scale bar: 5 μm.) FIG. 16C shows time-lapsed images from FDTD simulation videos demonstrating the interaction between light and brochosome arrays. When λ/D ranges from 0.5 to 1.2, brochosomes exhibit broadband light scattering. FIG. 16D shows a schematic illustration presenting the through-hole absorption effect on brochosomes when the wavelength of light is comparable to the through-hole size of brochosomes. FIG. 16E shows experimentally measured specular reflectance of synthetic brochosomes plotted against λ/d. Brochosomes with through-holes exhibit further reduced reflection when λ/d is below ˜1.4. FIG. 16F shows brochosomes with through-holes can further reduce the reflection by approximately 23 to 53% compared to those without through-holes. FIGS. 16G-16H show time-lapsed images from FDTD simulation videos demonstrating the interaction between light and brochosome arrays. For brochosomes with through-holes, light passes through the through-holes and becomes trapped inside the cavity when λ/d<1.4. Conversely, light cannot pass through the through-holes when λ/d>1.4. The color bar indicates the relative intensity of the electrical field E².

FIGS. 17A-17B depict Mie scattering efficiency of a highly reflective nickel metal sphere against dimensionless wavelength (λ/D). The red line was calculated based on EQ. 4. FIG. 17A shows the ratio between the wavelength of UV-visible light and the diameter of leafhopper brochosomes falls within the Mie scattering regime (8). FIG. 17B shows the diameters of the synthetic brochosomes in this study were designed to fall within the Mie scattering regime.

FIGS. 18A-18B depict a schematic illustration of the FDTD simulation set-up in infinite brochosome arrays (FIG. 18A) and single brochosomes (FIG. 18B), with or without through-holes. The time-lapsed images are from the FDTD simulation movies demonstrating Mie scattering of light on brochosome arrays (FIG. 18A) and a single brochosome (FIG. 18B). When the particle diameter D is comparable to wavelength λ, (i.e., λ/D ranges from 0.5 to 1.2), brochosomes exhibit broadband light scattering in which the light is fully reflected without entering the through-holes. The diameter of brochosome in these simulations is 20 μm. The color bar indicates the relative intensity of the electrical field |E|².

FIG. 19 depicts a theoretical prediction of the dimensionless critical wavelength of light, λ, passing through a hole of diameter d. The data was plotted based on a theoretical model from the literature (7).

FIGS. 20A-20B depict simulated total reflection spectra of brochosome arrays using the finite-difference time-domain method. FIG. 20A is a plot showing the total reflectance of brochosomes against dimensionless wavelength (λ/d, i.e., the ratio of incident wavelength λ and through-hole diameter d). Insets are schematic illustrations of a brochosome with through-holes (right-bottom) and a brochosome without through-holes (left-top). FIG. 20B is a plot showing the percentage reduction of the antireflection of brochosomes with and without through-hole structures.

FIGS. 21A-21B depict simulated specular reflection spectra of brochosome arrays using the finite-difference time-domain method. FIG. 21A is a plot showing the specular reflectance of brochosomes against dimensionless wavelength (λ/d, i.e., the ratio of incident wavelength λ and through-hole diameter d). FIG. 21B is a plot showing the percentage reduction of the reflectance of brochosomes with and without through-hole structures.

FIG. 22 depicts simulated absorption cross section spectra of single brochosome particles using the finite-difference time-domain method. When the dimensionless wavelength is comparable to or less than ˜1.5, the single brochosome particle with through-holes has a larger absorption cross section, indicating greater efficiency in absorbing light compared to those without through-holes.

FIGS. 23A-23D depict dependence of the observed through-hole effect on the packing density of synthetic brochosomes. FIG. 23A shows experimentally measured specular reflection on a series of brochosomes, both with and without through-holes, arranged at 23% packing density (FIG. 23B), 43% packing density (FIG. 23C), and 91% packing density (FIG. 23D). The through-hole effect is more evident when the brochosomes are arranged in a closely packed lattice with approximately 91% packing density (the highest particle packing density in two dimensions). Note that a lower packing density exposes more flat area and increases reflectance. Scale bar in SEM images: 20 μm. T.H. denotes ‘through-hole’ in the figure legend.

FIGS. 24A-24B depict characteristic lengths of natural brochosomes and the corresponding optical regimes. FIG. 24A is a scatter plot showing the diameters of brochosomes (closed red circles), and FIG. 24B shows the diameters of through-hole (open blue circles) plotted against leafhopper body length across different leafhopper species. These two characteristic lengths of natural brochosomes remain relatively consistent, with brochosome diameters ranging from approximately 300 nm to 700 nm, and through-hole diameters ranging from about 100 nm to 280 nm, regardless of the leafhopper body length (ranging from approximately 3 mm to 9 mm). The red area highlights the region of Mie scattering of visible light, as predicted by EQ. 4, while the blue area indicates UV absorption via the through-hole effect, as predicted by EQ. 6. The color bar represents the visual spectra of some of the leafhoppers' predators, including birds and lizards (42, 43). The characteristic lengths of brochosomes were obtained from experimental measurements and the literature (18).

FIGS. 25A-25B depict SEM images showing the leafhopper wing covered with brochosomes (FIG. 25A) and the leafhopper wing after complete removal of brochosomes (FIG. 25B).

FIGS. 26A-26D depict optical properties of leafhopper wings (Gyponana serpenta). FIG. 26A shows experimentally measured specular reflection on leafhopper wings with brochosomes and leafhopper wings without brochosomes. FIG. 26B shows brochosomes on leafhopper wings can further reduce the reflection by approximately ˜28% to ˜86% in the UV range (i.e., ˜300 nm<λ<˜400 nm), and by ˜28% to ˜68% in the visible light range (˜400 nm<λ<˜700 nm), compared to a bare leafhopper wing without brochosomes. FIG. 26C shows experimentally measured specular reflection on moth wings (Cephonodes hylas) with the nano-pillars and moth wings without nano-pillars. Reproduced from the data in reference (9). FIG. 26D shows that nano-pillars on moth wings can further reduce the reflection by approximately 69% compared to moth wings without nano-pillars.

FIGS. 27A-27C depict disorder analysis of the “through-hole” effect. FIG. 27A is a SEM image showing synthetic brochosomes without through-holes arranged in a disordered array of about 350 μm by 350 μm. The packing density is approximately 63%. FIG. 27B is an SEM image showing synthetic brochosomes with through-holes arranged in the same disordered array. The diameter of the synthetic brochosome is 20 μm with the average through-hole diameter (d) approximately 5 μm. FIG. 27C shows experimentally measured specular reflection of synthetic brochosome arrays within an area of 150 μm by 150 μm using micro-FTIR. The wavelength of light (λ) ranges from 2.5 μm to 10 μm corresponding to a dimensionless wavelength (λ/d) from 0.5 to 2.0. When the wavelength of light is comparable to the through-hole size, the reflectance of brochosomes with through-holes is lower compared to those without through-holes.

FIGS. 28A-28C depict thermal signature manipulation by BLPs. FIG. 28A shows an optical image of a leafhopper Gyponana serpenta. Scale bar, 1 mm. Insets: A scanning electron microscopy (SEM) image of leafhopper-produced brochosomes. Scale bar, 500 nm. FIG. 28B shows, top to bottom, three-dimensional (3D) models of BLPs with op-BLPs and cp-BLPs, respectively. FIG. 28C shows a schematic of information camouflage and display by BLPs. Information is concealed in the binary array formed by BLPs, which is camouflaged in the visible range but can be displayed under infrared (IR) imaging systems.

FIGS. 29A-29D depict the design of brochosome-like pixels (BLPs). FIGS. 29A-29B show a front view and a cross-sectional view of the op-BLPs. FIGS. 29C-29D show a front view and a cross-sectional view of the cp-BLPs. d and D represent the diameters of the pores and the outer diameter of the BLPs, respectively.

FIGS. 30A-30G depict multispectral design of BLPs. FIG. 30A shows a schematic of light-BLP interactions. FIG. 30B shows pore diameter to BLP diameter ratio d/D of natural brochosomes produced by various leafhoppers, from which an averaged ratio of 0.28 is acquired and used as the initial design of the BLPs. Data are acquired from (31). FIG. 30C shows simulated BSDFs in the visible range for both a cp-BLP (solid lines) and an op-BLP (dashed-dotted lines) with respect to normal illumination. a.u., arbitrary units. FIG. 30D shows simulated absorption cross-sectional areas σ of an op-BLP, a cp-BLP, and a sphere. The outer diameter of the simulated BLPs and sphere is 20 μm, and the material is nickel (Ni). FIG. 30E shows excess absorption cross-sectional areas Δσ of BLPs compared to the sphere. FIGS. 30F-30G show simulated spatial distribution of the magnitude of the electrical field (λ=4.5 μm, marked by the dashed line in FIG. 30E) near an op-BLP and a cp-BLP, respectively.

FIGS. 31A-31E depict long-wavelength field profiles showing the cutoff effect of the BLP absorption. FIG. 31A shows simulated excess absorption cross sections with dashed lines marking the wavelengths at which the field profiles are plotted. FIGS. 31B-31C show field profiles near an op-BLP and a cp-BLP at the wavelength of 6.8 μm, respectively. FIGS. 31D-31E show field profiles near an op-BLP and a cp-BLP at the wavelength of 11.9 μm, respectively.

FIGS. 32A-32B depict the necessity and effectiveness of brochosome-like pixels. FIG. 32A shows simulated absorption cross sections of hollow Ni spheres (D=20 μm) with only one open/closed pore on the top, which show a much weaker contrast than those of op-BLP and cp-BLP. Insets: 3D models of the simulated structures. FIG. 32B shows Fourier-transform infrared reflection (FTIR) spectra of both the op-BLP and cp-BLP arrays showing the infrared reflection contrast between BLP arrays of different types.

FIGS. 33A-33F depict quantitative analysis of camouflage and display under different imaging systems. FIGS. 33A-33C show images of BLP arrays taken under a visible microscope in the bright field mode, dark field mode, and infrared microscope, respectively. Scale bar: 100 μm. FIGS. 33D-33F show pixels brightness distributions in the background (cyan) and patterns (red) for the three images, respectively. The analyzed regions are highlighted in the corresponding images by the cyan and red boxes, respectively. In the bright field image, pixel distributions in the background and pattern are nearly identical, providing maximum camouflage effect. In the dark field image, because the dark-field imaging systems amplify the slight difference in the scattering behaviors between the two types of BLPs, the pixel distributions in the background and pattern follow similar trends but with a minor difference, which leads to a suppressed visibility of the ‘C’ and ‘P’ pattern. In the IR image, pixel brightness distributions in the background and pattern are significantly different, especially for brightness smaller than 0.5, which provides the optimized display effect. The analysis method is adopted from (35). Images analyzed were imported to MATLAB and converted to grayscale; pixel values were normalized to 0 to 1 before counting. Note here, ‘pixel’ refers to the real pixel forming the images, not the brochosome-like pixels that were designed.

FIGS. 34A-34F depict emissivity contrast of BLPs. FIGS. 34A-34B show SEM images of fabricated op-BLP array and cp-BLP arrays, respectively. Scale bars, 20 μm. FIGS. 34C-34D show measured spatial distribution of emissivities of op-BLP and cp-BLP arrays, respectively. Scale bars, 50 μm. Insets: Typical local enlarged images of single BLPs from which their emissivities are evaluated. FIGS. 34E-34F show simulated spectral-directional absorptivity (SDA) of op-BLP and cp-BLP arrays, respectively. The averaged emissivities can be calculated according to EQS. 7-9 (see Example 4, Material and Methods), in which the integration domains are marked by the dashed white boxes.

FIGS. 35A-35C depict quantitative analysis of visible images of the BLP arrays. FIGS. 35A-35B show images of a 9-by-9 op-BLP array and a 9-by-9 cp-BLP array, respectively. Images are imported to and processed by ImageJ for analysis. Scale bars: 50 μm. FIG. 35C shows calculated pattern energy distribution among patterns of different sizes (measured by pixels) by the quantitative color pattern analysis method (33). Note here, ‘pixel’ refers to the real pixels forming the images, not the brochosome-like pixels that were designed. The two overlapped curves suggest that the two arrays appear almost identical in the optical images.

FIGS. 36A-36D depict visible camouflage and infrared display based on optimized BLPs. FIGS. 36A-36B show optimization of the shape and size of pores in BLPs, respectively. Scale bars, 60 μm. FIG. 36A-a shows the design of the BLPs array, with P-1 to P-4 representing BLPs with circular open pores, circular closed pores, polygon open pores, and polygon closed pores, respectively. The diameter of the circular pores is 3.7 μm, and diameter of polygon pores is 5 μm. In FIG. 36B-a, P-1 to P-8 represent op-BLPs with d=3.7 μm, bare spheres, op-BLPs with d=4.0 μm, cp-BLPs with d=4.0 μm, op-BLPs with d=5.0 μm, cp-BLPs with d=5.0 μm, op-BLPs with d=6.0 μm, and cp-BLPs with d=6.0 μm, respectively. FIGS. 36A-36B also show SEM images (FIG. 36A-b and FIG. 36B-b), optical images (FIG. 36A-c and FIG. 36B-c), and infrared images (FIG. 36A-d and FIG. 36B-d) of the designed BLP arrays. For the best visible camouflage and infrared display effect, combination of circular op-BLPs/cp-BLPs were used in the demonstration (red and yellow combination in FIG. 36A-a). FIG. 36C shows a BLP array forming letters C and P. Scale bar, 100 μm. FIG. 36D shows a BLP array forming a QR code (storing the address of the homepage of Carnegie Mellon University). Scale bar, 150 μm. FIG. 36C-a and FIG. 36D-a show SEM images of the BLP array; FIG. 36C-b and FIG. 36D-b show optical images of the BLP arrays. The patterns are camouflaged through background matching; FIG. 36C-c, FIG. 36D-c, FIG. 36C-d, and FIG. 36D-d show infrared images and calculated spatial distribution of emissivity based on the infrared images, displaying patterns due to the emissivity contrast between different BLPs. The infrared images in FIG. 36C-d and FIG. 36D-d are taken using the objectives with ×20 and ×12 magnifications, respectively.

FIGS. 37A-37D depict a closely packed brochosome-like pixel array for high pixel-density display. FIG. 37A shows BLPs with surface features of different shapes forming a closed packed array. P-1 to P-4 represent BLPs with circular open pores (d=3.7 μm), with circular closed pores (d=3.7 μm), with polygon open pores (d=4.5 μm), and with polygon closed pores (d=4.5 μm), respectively. FIG. 37B shows a SEM image of the closely packed BLP array. FIGS. 37C-37D shows a visible and an infrared image of the closely packed BLP array taken with 20× objectives. The optimized BLP pairs also (P-1 and P-2) retain the visible range concealment and infrared contrast when they are closely packed.

FIGS. 38A-38G depict thermal stability analysis of a 3D-printed BLP array. FIGS. 38A-38E show infrared images of the BLP array captured at 50° C., 80° C., 100° C., 110° C., and 30 minutes after maintained at 110° C., respectively. In FIGS. 38A-38D, the sample are maintained at designated temperatures for 2 minutes before the images are taken to ensure the temperature uniformity. FIGS. 38F-38G show SEM images of the BLP arrays after being kept at 110° C. for 30 minutes and cooled down to room temperature. Scale bar: FIGS. 38A-38F, 50 μm; FIG. 38G, 10 μm. The specification of the BLP array is detailed in FIGS. 37A-37D. Infrared images are captured with a 12× objective.

FIGS. 39A-39E depict tilted-angle thermal mapping measurements. FIGS. 39A-39B show infrared emissivity of an op-BLP array (FIG. 39A) and a cp-BLP array (FIG. 39B) respectively when tiled by 2 degrees. FIGS. 39C-39D show infrared emissivity of an op-BLP array (FIG. 39C) and a cp-BLP array (FIG. 39D) respectively when tiled by 6 degrees. FIG. 39E depicts arrays showing letters ‘C’ and ‘P’ when viewed with a 6-degree tilting. The bottom blurred part of the image is out of focus, therefore extraction of patterned data at a larger tilting angle will be limited by the focal depth of microscopes. The tilted angles are estimated by comparing the sizes of the measured arrays to their original sizes. Arrows mark the ‘downhill’ direction of the tilted samples. All tilted-angle thermal mapping measurements were conducted with a 12× objective.

FIGS. 40A-40E depict optimization of infrared images of the BLP QR code. FIGS. 40A-40B show blurring the IR images by applying Gaussian filleters. The original IR image in FIG. 40A is taken with a 12× objective. 2-D Gaussian filter is applied to the original image in MATLAB to generate the blurred image in FIG. 40B. FIGS. 40C-40E show blurring the IR images by de-focusing the imaging system. Images are taken with a 4× objective. IR images of the BLP QR code are easier to scan after proper blurring.

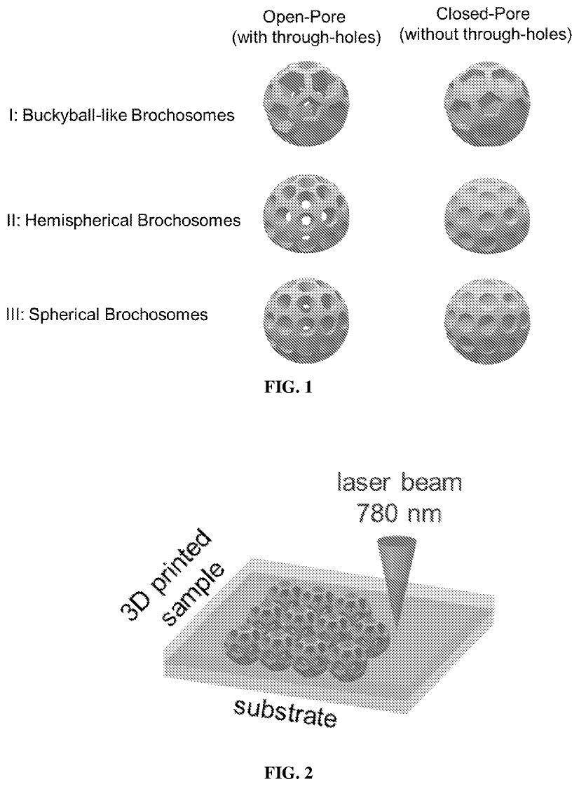

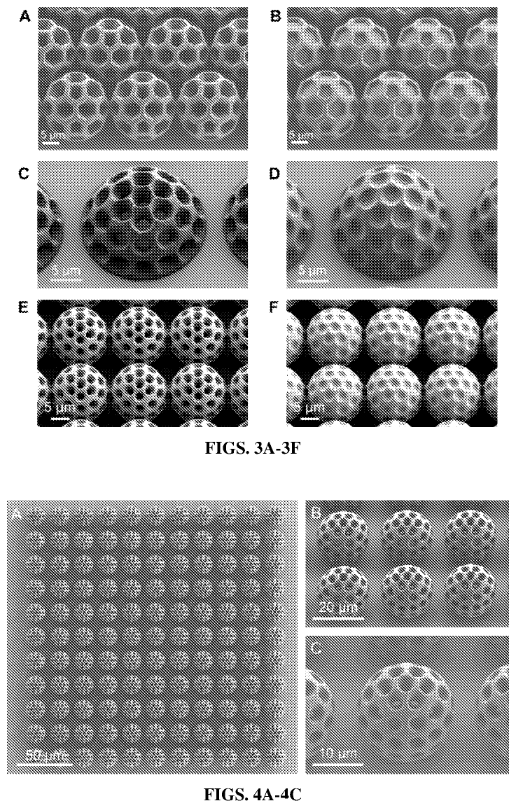

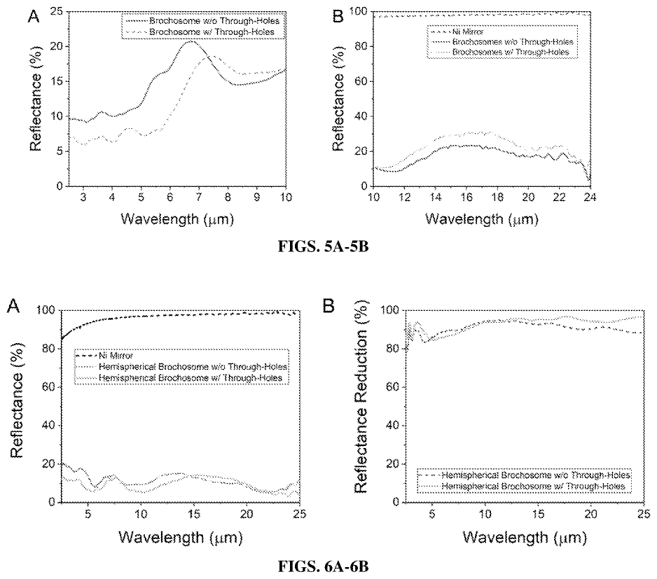

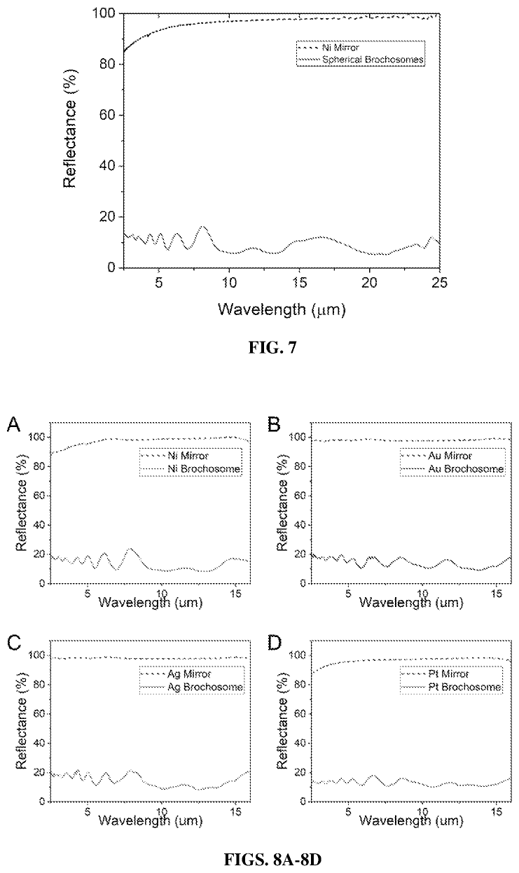

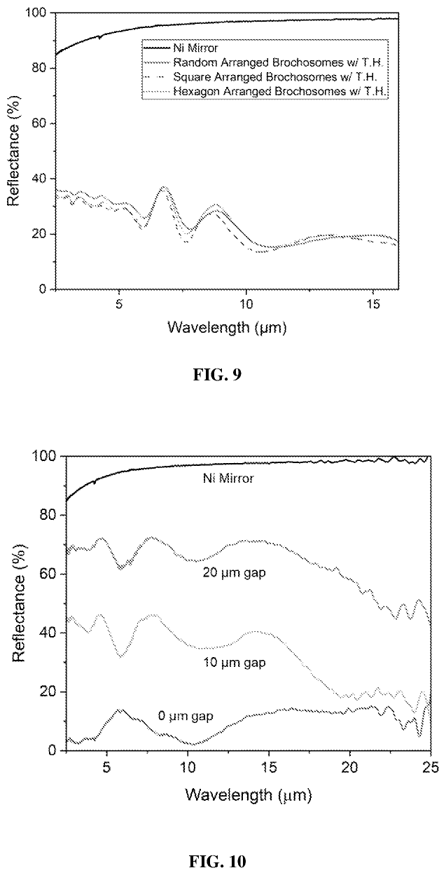

### DETAILED DESCRIPTION

The present invention can be understood more readily by reference to the following detailed description of the invention and the Examples and Figures included therein.

Before the present compounds, compositions, articles, systems, devices, and/or methods are disclosed and described, it is to be understood that they are not limited to specific synthetic methods unless otherwise specified, or to particular reagents unless otherwise specified, as such may, of course, vary. It is also to be understood that the terminology used herein is for the purpose of describing particular aspects only and is not intended to be limiting. Although any methods and materials similar or equivalent to those described herein can be used in the practice or testing of the present invention, example methods and materials are now described.

All publications mentioned herein are incorporated herein by reference to disclose and describe the methods and/or materials in connection with which the publications are cited. The publications discussed herein are provided solely for their disclosure prior to the filing date of the present application. Nothing herein is to be construed as an admission that the present invention is not entitled to antedate such publication by virtue of prior invention. Further, the dates of publication provided herein can be different from the actual publication dates, which can require independent confirmation.

It is appreciated that certain features of the disclosure, which are, for clarity, described in the context of separate aspects, can also be provided in combination with a single aspect. Conversely, various features of the disclosure, which are, for brevity, described in the context of a single aspect, can also be provided separately or in any suitable subcombination. Unless defined otherwise, all technical and scientific terms used herein have the same meaning as commonly understood by one of ordinary skill in the art. Methods and materials similar or equivalent to those described herein can be used in the practice or testing of the present disclosure.

### Definitions

In this specification and in the claims that follow, reference will be made to a number of terms, which shall be defined to have the following meanings:

Throughout the description and claims of this specification, the word “comprise” and other forms of the word, such as “comprising” and “comprises,” means including but not limited to, and are not intended to exclude, for example, other additives, segments, integers, or steps. Furthermore, it is to be understood that the terms comprise, comprising, and comprises as they relate to various aspects, elements, and features of the disclosed invention also include the more limited aspects of “consisting essentially of” and “consisting of.” As used herein, the singular forms “a,” “an,” and “the” include plural referents unless the context clearly dictates otherwise. Thus, for example, reference to a “polymer” includes aspects having two or more such polymers unless the context clearly indicates otherwise.

Ranges can be expressed herein as from “about” one particular value and/or to “about” another particular value. When such a range is expressed, another aspect includes from the one particular value and/or to the other particular value. Similarly, when values are expressed as approximations, by use of the antecedent “about,” it will be understood that the particular value forms another aspect. It should be further understood that the endpoints of each of the ranges are significant both in relation to the other endpoint, and independently of the other endpoint. The term “about” can also mean within 5%, e.g., within 4%, 3%, 2%, 1%, or 0.5% of the stated value.

As used herein, the terms “optional” or “optionally” mean that the subsequently described event or circumstance may or may not occur, and that the description includes instances where said event or circumstance occurs and instances where it does not.

References in the specification and concluding claims to parts by weight of a particular element or component in a composition denotes the weight relationship between the element or component and any other elements or components in the composition or article for which a part by weight is expressed. Thus, in a compound containing 2 parts by weight of component X and 5 parts by weight component Y, X and Y are present at a weight ratio of 2:5, and are present in such ratio regardless of whether additional components are contained in the compound.

A weight percent (wt. %) of a component, unless specifically stated to the contrary, is based on the total weight of the formulation or composition in which the component is included.

For the terms “for example” and “such as,” and grammatical equivalences thereof, the phrase “and without limitation” is understood to follow unless explicitly stated otherwise.

### Methods

In an aspect, provided is a method of forming a synthetic brochosome, comprising: irradiating a portion of a photoresist coated onto a substrate with a focused radiation beam or light sheet, wherein the beam or light sheet is moved along a designated pathway within the photoresist to polymerize the portion of the photoresist irradiated by the beam or light sheet; and removing a portion of the photoresist from the substrate that is not irradiated and not polymerized by the beam or light sheet, thereby providing a synthetic brochosome.

In some aspects, other 3D printing methods such as volumetric additive manufacturing (Kelly, B. et al., Volumetric additive manufacturing via tomographic reconstruction. Science 2019, 363, 1075-1079), continuous liquid interface production (CLIP) (Tumbleston, J. R. et al., Continuous liquid interface production of 3D objects. Science 2015, 347, 1349-1352), and ultrafast laser patterning with light sheets (Han, F. et al., Three-dimensional nanofabrication via ultrafast laser patterning and kinetically regulated material assembly. Science 2022, 378, 1325-1331) can also be used to fabricate the synthetic brochosomes.

In some aspects, the beam or light sheet is moved along a designated pathway within the photoresist according to predetermined coordinates. In some aspects, the beam or light sheet is moved along an x, y, and/or z direction relative to the position of the photoresist. In some aspects, the position of the photoresist is moved along an x, y, and/or z direction relative to the beam or light sheet. In some aspects, the beam or light sheet is a 780 nm laser beam.

In some aspects, the photoresist comprises IP-DIP, IP-S, IP-PDMS, IP-n162, IP-Visio, IP-Q, IP-G, IP-L, epoxy-based SU-8, hybrid sol-gel Ormocer or Ormocomp, or any combinations thereof. IP-DIP is an organic negative-tone photoresist. Its empirical molecular formula is CH₂N_{0.001}O_{0.34} (O. Stein et al., “Handling and assembling of low-density foam structures fabricated by two-photon polymerization.” Nanoengineering: Fabrication, Properties, Optics, and Devices XIV. Vol. 10354. SPIE, 2017). It is a photoresist resin that is 60-80% pentaerythritol triacrylate (A. V. Pisarenko, et al., “DLW-printed optical fiber micro-connector kit for effective light coupling in optical prototyping.” Optik 201 (2020): 163350). IP-S is also an organic negative-tone photoresist and it has an empirical molecular formula as CH_{1.72}N_{0.086}O_{0.37}.

In some aspects, the substrate comprises silicon, glass, quartz, indium tin oxide coated glass (ITO-glass), metals such as stainless steel, carbon steel, aluminum, titanium, nickel alloy, copper, brass, bronze; plastics such as polycarbonate, poly(methyl methacrylate); or other infrared transparent materials such as calcium fluoride, germanium, zinc selenide, barium fluoride, sapphire, gallium arsenide, BK7 schott glass; or any combination thereof.

In some aspects, the portion of the photoresist removed from the substrate is removed by contacting the substrate with developers such as 1-methoxy-2-propanol acetate or propylene glycol methyl ether acetate for from about 10 to about 25 minutes, or from about 12 minutes to about 24 minutes, or from about 14 minutes to about 22 minutes, or from about 16 minutes to about 20 minutes, or from about 10 minutes to about 16 minutes, or from about 12 minutes to about 14 minutes, or from about 20 minutes to about 25 minutes, or from about 22 minutes to about 24 minutes. In some aspects, the portion of the photoresist removed from the substrate is removed by further contacting the substrate with isopropyl alcohol for from about 2 minutes to about 5 minutes, or from about 2.5 minutes to about 4.5 minutes, or from about 3 minutes to about 4 minutes, or from about 2 minutes to about 3 minutes, or from about 4 minutes to about 5 minutes.

In some aspects, the method further comprises coating the synthetic brochosome with a second material using electron beam evaporation or sputtering methods, wherein the second material comprises nickel, gold, silver, platinum, aluminum, chromium, cobalt, copper, germanium, iron, molybdenum, palladium, rhenium, titanium, tungsten. alumina, silicon dioxide, titanium dioxide, carbon, parylene, or any combination thereof.

### Composition

In an aspect, provided is a synthetic brochosome comprising a photoresist having a conductive coating.

In some aspects, the photoresist comprises IP-DIP, IP-S, IP-PDMS, IP-n162, IP-Visio, IP-Q, IP-G, IP-L, epoxy-based SU-8, hybrid sol-gel Ormocer or Ormocomp, or any combinations thereof

In some aspects, the conductive coating comprises nickel, gold, silver, platinum, aluminum, chromium, cobalt, copper, germanium, iron, molybdenum, palladium, rhenium, titanium, tungsten and carbon, or any combination thereof. In some aspects, the conductive coating can be physically or chemically deposited onto synthetic brochosomes.

In some aspects, the synthetic brochosome has a particle diameter of from about 5 μm to about 100 μm, including exemplary values of about 10 μm, about 15 μm, about 20 μm, about 25 μm, about 30 μm, about 35 μm, about 40 μm, about 45 μm, about 50 μm, about 55 μm, about 60 μm, about 65 μm, about 70 μm, about 75 μm, about 80 μm, about 85 μm, about 90 μm, about 95 μm. In some aspects, the synthetic brochosomes have a buckyball-like geometry or a spherical shape or a hemispherical shape.

In some aspects, the synthetic brochosome further comprises through-holes. The size of through-hole is characterized by a characteristic diameter D, defined as D=4A/P where A is the cross-section area of the through-hole and P is the perimeter of the through-hole. In some aspects, the synthetic brochosome has a through-hole size of from about 1 μm to about 30 μm, including exemplary values of about 2 μm, about 4 μm, about 6 μm, about 8 μm, about 10 μm, about 12 μm, about 14 μm, about 16 μm, about 18 μm, about 20 μm, about 22 μm, about 24 μm, about 26 μm and, about 28 μm. In some aspects, the synthetic brochosome has a through-hole wall thickness of about 5%, about 7%, about 10% of the diameter of brochosomes, varying from about 500 nm to about 10 μm including exemplary values of about 500 nm, about 1 μm, about 1.5 μm, about 2 μm, about 2.5 μm, about 3 μm, about 3.5 μm, about 4 μm, about 4.5 μm, about 5 μm, about 5.5 μm, about 6 μm, about 6.5 μm, about 7 μm, about 7.5 μm, about 8 μm, about 8.5 μm, about 9 μm, and about 9.5 μm. In some aspects, the shape of the through-holes can be circular, decagonal, nonagonal, octagonal, heptagonal, hexagonal, pentagonal, quadrilateral, or triangular, or a combination of any of these shapes. In some aspects, the through-holes are arranged in a crystal or quasiperiodic-crystal or even random pattern including but not limited to buckyball pattern, honeycomb pattern, or circular loop pattern. In some aspects, the synthetic brochosome further comprises through-holes, indentations, surface cavities, or closed-pores. In some aspects, the number of through-holes or cavities, n, on each brochosome range from n=1 to n=nₘₐₓ, where nₘₐₓ be estimated by

$${n}_{max} ≅ \frac{π}{2 \sqrt{3}} {( \frac{{D}_{b}}{D} )}^{2} ,$$

where D_{b} is the diameter of the synthetic brochosome and D is the characteristic diameter of the through-hole or cavity. In some aspects, the synthetic brochosome further comprises a mixture of through-holes and cavities.

In some aspects, the synthetic brochosome has a porosity of from about 50% to 95% including exemplary values of about 55%, about 60%, about 63.7%, about 65.7%, about 70%, about 75%, about 80%, about 85%, about 90%.

In some aspects, the synthetic brochosome has a shell wall thickness of about 13% to 20% of the brochosome diameters varying from about 1 μm to about 20 μm including exemplary values of about 2 μm, about 3 μm, about 4 μm, about 5 μm, about 6 μm, about 7 μm, about 8 μm, and about 9 μm, about 10 μm, about 11 μm, about 12 μm, about 13 μm, about 14 μm, about 15 μm, about 16 μm, about 17 μm, about 18 μm, about 19 μm.

In some aspects, the synthetic brochosomes are designed and engineered with a set of geometrical ratios that closely mimics the common geometry of natural brochosomes.

In some aspects, the synthetic brochosome has a particle diameter of from about 5 μm to about 100 μm, including exemplary values of about 10 μm, about 15 μm, about 20 μm, about 25 μm, about 30 μm, about 35 μm, about 40 μm, about 45 μm, about 50 μm, about 55 μm, about 60 μm, about 65 μm, about 70 μm, about 75 μm, about 80 μm, about 85 μm, about 90 μm, about 95 μm. In some aspects, the synthetic brochosomes have a buckyball-like geometry or a spherical shape or a hemispherical shape.

In some aspects, the synthetic brochosomes has a buckyball geometry and comprises 12 pentagonal and 20 hexagonal through-holes interconnected by a hollow core, or 12 pentagonal and 20 hexagonal non-through-hole cavities on the brochosome surface.

In some aspects, the synthetic brochosomes has a spherical geometry and comprises 55 circular through-holes interconnected by a hollow core, or 55 circular non-through-hole cavities. In some aspects, the synthetic brochosomes has a hemispherical geometry and comprises 31 circular through-holes, or 55 circular non-through-hole cavities.

In another aspect, provided is a coated substrate comprising a coating of any of the disclosed synthetic brochosomes disposed on a substrate.

In some aspects, the coating has a reflectance of from about 5% to about 20%, including exemplary values of about 6%, about 8%, about 10%, about 12%, about 14%, about 16%, and about 18%, at a wavelength in a range from about 2.5 μm to about 25 μm. In some aspects, the layer is a close-packed monolayer of synthetic brochosomes. In some aspects, the layer is non-close packed monolayer of synthetic brochosomes.

In some aspects, the synthetic brochosomes can be arranged in hexagonal close-packing, square close-packing, or other arbitrary patterns.

In some aspects, the inter-particle gap distance between individual synthetic brochosomes shall be smaller or equal to the characteristic diameter of the through-holes or cavities of the brochosomes for maximized antireflection.

Based on experimental and modeling results it was found that the specular infrared reflectance on an exemplary synthetic brochosome coating can be reduced from about 85%-99% (a flat reflective control) to from about 5% to about 20%, or from about 6% to about 18%, or from about 8% to about 16%, or from about 10% to about 14%, or from about 5% to about 10%, or from about 6% to about 8%, or from about 14% to about 20%, or from about 16% to about 18%. In particular, by rational design of the secondary through-holes to have a dimension larger than or comparable to a desirable wavelength, the infrared light reflection can be significantly reduced. In a broad range of wavelength, by rational design of the primary dimension of the synthetic brochosome to have a wavelength-to-diameter ratio of from about 0.1 to about 3 (or from about 0.25 to about 2.75, or from about 0.5 to about 2.5, or from about 0.75 to about 2.25, or from about 1 to about 2, or from about 1.25 to about 1.75, or from about 0.1 to about 1.25, or from about 0.25 to about 1, or from about 0.5 to about 0.75, or from about 1.75 to about 3, or from about 2 to about 2.75, or from about 2.25 to about 2.5), the infrared light can be broadly scattered and reflectance can be reduced from about 85%-99% to approximately 20%.

By adjusting the gap distance between the synthetic brochosomes printed on a reflective substrate, one can engineer the specular reflectance from about 5% to up to approximately 99% in a wavelength range from 2.5 μm to 25 μm (or from about 3 μm to about 24 μm, or from about 4 μm to about 22 μm, or from about 6 μm to about 20 μm, or from about 8 μm to about 22 μm, or from about 10 μm to about 20 μm, or from about 12 μm to about 18 μm, or from about 14 μm to about 16 μm, or from about 2.5 μm to about 14 μm, or from about 4 μm to about 12 μm, or from about 6 μm to about 10 μm, or from about 16 μm to about 25 μm, or from about 18 μm to about 24 μm, or from about 16 μm to about 22 μm, or from about 18 μm to about 20 μm.

The synthetic brochosomes can also be used as an infrared information encryption material. The spherical brochosomes with through-holes and those without through-holes could form a pair pixel twins to act as information binary digit such as zero and one. The experimentally measured thermal emissivity of these spherical brochosomes is different from each other, i.e., 0.419 and 0.3073, respectively. However, their appearance under visible light is similar to each other. The synthetic brochosome can be used for information storage and encryption. An array of exemplary synthetic brochosomes were patterned into a quick-response (QR) code (version 1, ECC level L) containing the web address of Carnegie Mellon University, with the spherical brochosomes without through-holes forming the QR code and the spherical brochosomes with through-holes forming the background.

### EXAMPLES

### Example 1—Fabrication of Synthetic Brochosomes by 3D Printing

The synthetic brochosomes were fabricated by a two-photon polymerization 3D printing method. The 3D computer-aided design (CAD) files of synthetic brochosomes were designed using the software SolidWorks. The 3D printing process was carried out using a Nanoscribe 3D printer, which can achieve a lateral resolution of approximately 200 nm, and a vertical resolution of approximately 300 nm. To create the synthetic brochosome structures, a photoresist called IP-DIP (approximately 50 μL) was added onto a silicon substrate, and the photoresist was polymerized by a 780 nm laser beam. The synthetic brochosome structures were printed by moving the focus point of the laser beam in accordance with the 3D file instructions. Finally, the uncured polymer was removed by immersing the sample in the photoresist developer called 1-methoxy-2-propanol acetate for 10 minutes, followed by rinsing with isopropyl alcohol for 2 minutes. The 3D printed synthetic brochosomes were conformally coated with a layer of 100-nm nickel using e-beam sputter (Temescal FC-2000, Ferrotec, USA). The temperature of the samples during sputtering process was maintained around 16° C. The fabrication scheme is shown in FIG. 2.

TABLE 1
Manufacturing Parameters by a 3D Printer

| | | | | Brochosome | Brochosome |
|---|---|---|---|---|---|
| | | | Open/Closed | diameter | pore diameter |
| Sample# | Material | Geometry | pore? | (μm) | (μm) |
| 1 | IP-Dip and | Buckyball | Open and | 20 | 4 and 6 |
| | nickel | | closed | | |
| 2 | IP-Dip and | Hemisphere | Open and | 20 | 3.7 |
| | nickel | | closed | | |
| 3 | IP-Dip | Sphere | Open and | 20 | 3.7 |
| | and nickel | | closed | | |
| 4 | IP-Dip | Sphere | Open and | 20 | 3.7 |
| | and gold | | closed | | |
| 5 | IP-Dip | Sphere | Open and | 20 | 3.7 |
| | and silver | | closed | | |
| 6 | IP-Dip | Sphere | Open and | 20 | 3.7 |
| | and | | closed | | |
| | platinum | | | | |

### Example 2—Antireflective Coating in Infrared Range

Representative samples of synthetic brochosomes were created by first designing the computer-aid-designs using the software SolidWorks. The buckyball-like synthetic brochosomes with diameters of approximately 20 μm and through-hole diameters around 4 μm and 6 μm were fabricated using the 3D printing method. Their geometries are carefully designed to ensure that the printed structures were significantly larger than the voxel size of the 3D printer. The 3D printed synthetic brochosomes had 12 pentagonal and 20 hexagonal through-holes interconnected by a hollow core, mimicking the precise geometries of natural brochosomes. To emulate the dense packing arrangement of natural brochosomes observed on leafhoppers' wings, the synthetic brochosomes are printed in a hexagonal close-packed (HCP) lattice. The fabricated sample had an array of 20 by 20 synthetic brochosomes, which covers an area of approximately 400 μm by 350 μm. The shell thickness and through-hole wall thickness of synthetic brochosomes are approximately 7% and 20% of the overall diameter D, respectively, closely mimicking the characteristics of natural brochosomes.

The antireflection capability of the printed buckyball-like brochosomes are characterized using a micro-Fourier-transform infrared spectroscopy. The experimental measurements demonstrated that synthetic brochosomes with through-holes can effectively reduce specular reflection in the wavelength range from 2.5 μm to 24 μm by up to approximately 94%. Specifically, there are two distinct antireflection regimes by analyzing the reflection spectra of synthetic brochosomes with and without through-holes. In the first regime, when the wavelength of light is comparable to the diameter of synthetic brochosomes, D, (i.e., ˜0.5≤λ/D≤˜1), but larger than the through-hole diameters, d, a broadband antireflection effect is observed. In this regime, both synthetic brochosomes with and without through-holes exhibited a reduction in reflection of approximately 80% compared to a reflective flat nickel surface. In the second regime, when the wavelength of light is smaller than or comparable to the through-hole diameter, d, (i.e., λ/d<˜1.4), an additional reduction in reflection was observed of up to approximately 53% on synthetic brochosomes with through-holes compared to those without through-holes.

Electromagnetic waves in the IR range have important defense and security applications. For example, night vision technologies detect reflected IR signals from the object surfaces, whereas thermal imaging and tracking devices sense IR signals emitted from the objects for detection. The ability to create advanced bio-inspired coatings that possess tunable IR properties will enable new IR signature management, encryption devices, LiDAR and camouflage technologies for defense and security applications.

### Example 3—Information Encryption in the Infrared Range

Another example is using spherical synthetic brochosomes for information storage and encryption. The brochosomes were patterned as letters ‘C’ and ‘P’ using the spherical synthetic brochosomes without through-holes in the background formed by brochosomes with through-holes. In general, the brochosomes with through-holes will appear to be brighter that brochosomes without through-holes under infrared microscopes when they are of the same temperature. The mechanism of such structure-induced brightness difference relates to the through-hole enabled cavity effect: brochosomes with through-holes will allow infrared light to penetrate the structure and resonate inside the central cavity, which will increase the absorptivity of brochosome with through holes compared to those without through-holes. By Kirchhoff's Law in radiative heat transfer, such absorption difference will translate into the infrared emission contrast, causing the different brightness of the two kinds of brochosome under infrared microscopes. Here the closely square packed 20-μm-diameter brochosome pixels result in an effective pixel density of 1270 pixel per inch. It is demonstrated that in the visible range, the information is hidden if it is viewed by an optical microscope with a 20× magnification objective, from which the two kinds of spherical brochosomes are indistinguishable so that the patterns are buried into the background. However, the emissivity difference between the two kinds of brochosomes provides ample contrast to display the hidden patterns in the infrared range, which is taken with the same magnification but by an infrared microscope. Based on the calculated emissivity shown in FIG. 11D, the achieved spatially averaged thermal emissivity by the spherical brochosomes without through-holes is 0.33, compared to 0.13, the achieved spatially averaged thermal emissivity by the spherical brochosomes with through-holes, which result in the an effective contrast ratio of 2.5:1. The thermal emissivity of spherical brochosomes with and without through-holes were characterized by using a thermal mapping instrument in a wavelength range of 2.5 μm to 4.2 μm.

The spherical synthetic brochosomes were also fabricated as an array patterned as a QR code containing the web address of Carnegie Mellon University, with the spherical brochosomes without through-holes forming the QR code and those with through-holes forming the background. The size of the QR code is 21 pixels by 21 pixels with a 2-pixel margin on each side, resulting in a physical size of 0.5 mm by 0.5 mm. Compared with other nano/microstructure-based QR codes, the pixel size as well as the entire QR code size is much smaller than those based photonic crystals. The QR code is encrypted under visible light while it can be observed and scanned by common QR-code scanning applications in smart phones under IR light. The IR image of the QR code is taken by an objective with 12× magnification, and the visible image of the QR code is taken by a visible microscope with an objective the closest available magnification (10× magnification).

### Example 4—Geometric Design of Antireflective Leafhopper Brochosomes

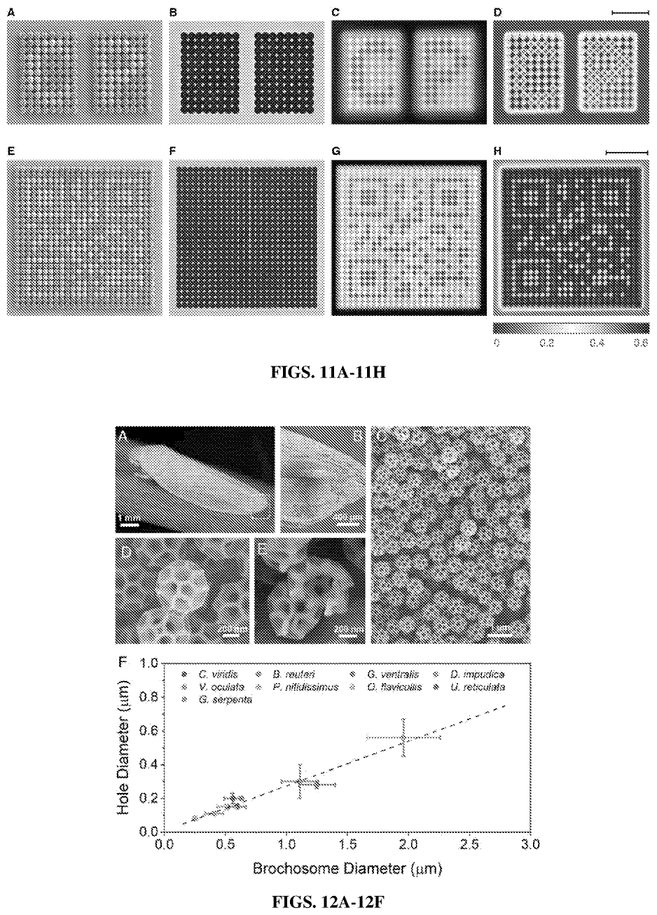

In nature, various animals (1-12) and plants (13-15) utilize complex hierarchical micro- and nano-scale materials to manipulate and interact with light, resulting in diverse optical effects. These effects range from structural coloring (5, 10, 16) to antireflection (2) and serve critical functions in signaling (10), sensing (3), communications (13, 15), and camouflage (12, 17). All of these natural optical materials are fully integrated with the biological body surfaces. In contrast, deployable optical materials are rare in the biological world. Brochosomes, however, are actively secreted and distributed by leafhoppers on their body surfaces through anointing and grooming behaviors after molting, forming a dense and evenly coated integumentary layer (18) (FIGS. 12A-12E and FIGS. 13A-13C).

Brochosomes are among the most sophisticated three-dimensional (3D) nanostructures observed in nature (19, 20). They are buckyball-shaped spheroids including hexagonal and pentagonal through-holes interconnected via a central cavity. Several potential functions of brochosomes have been proposed, including microbial prevention (21, 22), desiccation resistance (22), pheromone carrier (23), liquid repellency (24, 25), and antireflection (26). However, the form-to-function relationship of these intricate hierarchical materials remains elusive. In particular, the physical mechanisms underlying the natural brochosome geometry and their antireflection function have yet to be fully understood. The major obstacle stems from the highly sophisticated geometries of brochosomes. Replicating their precise structures—especially the hollow buckyball architecture with interconnected through-holes (FIG. 12E)—using synthetic materials remains an outstanding technological challenge.

Here, a study was conducted which utilized the two-photon polymerization 3D printing technique to fabricate synthetic brochosomes that accurately emulate the geometry of their natural counterparts. The study then investigated their antireflection characteristics through a combination of experimental, simulation, and scaling analyses. This study revealed two distinct antireflection regimes on brochosomes: a broadband antireflection regime when the wavelength is comparable to the brochosome diameter and a through-hole-enabled antireflection regime when the wavelength is smaller than or comparable to the through-hole diameter. These results demonstrated that brochosomes synergistically utilize their primary and secondary structures to achieve up to approximately ˜80 to ˜94% reduction in light reflection. Specifically, the experimental and simulation results showed that the primary spherical structures of brochosomes achieve a broadband reduction in light reflection by up to ˜80% due to the Mie scattering effect (33). And the secondary through-hole structures of brochosomes contribute to a further ˜53% reduction when the wavelength, a, is smaller than or comparable to the through-hole diameter, d. These findings unveiled the function of the through-holes in brochosomes as short-wavelength, low-pass filters. This unique mechanism enables brochosomes to trap short wavelength light (λ<1.5) inside the central cavity, further reducing light reflection. This is an identification of a through-hole-enabled antireflection mechanism in a biological system. It should be noted that this antireflection mechanism differs from the well-known “moth-eye” effect, which relies on an array of two-dimensional conical protuberances (2). The antireflection mechanisms in brochosomes introduce a distinct bioinspired design principle of structural antireflection coatings, enabling effective light manipulation in various optical applications.

### Materials and Methods

Materials: The leafhopper specimens were purchased from www.deadinsect.net. Silicon wafers were purchased from Addison Engineering Inc., USA. Photoresist IP-DIP was purchased from Nanoscribe GmbH & Co.

Characterization of the Insect Surfaces: The optical image of the leafhopper was captured using a digital camera equipped with a macro lens (ILCE-7M2, Sony, Japan; Mitakon 20 mm f/2, Zhongyi Optics, China). The nanoscopic view of the insect surfaces was obtained using a field emission scanning electron microscope (Merlin, Zeiss, Germany) with a 5-kV acceleration voltage. To prevent electron charging on the non-conductive biological specimens, a 10-nm layer of iridium was sputtered.

Fabrication of Synthetic Brochosomes: The synthetic brochosomes were fabricated by a two-photon polymerization 3D printing method. The 3D computer-aided design files of synthetic brochosomes were designed using the software SolidWorks. The 3D printing process was carried out using a 3D printer (Nanoscribe Photonic Professional GT3D). To create the synthetic brochosome structures, a photoresist called IP-DIP (approximately 50 μL) was added onto a silicon substrate, and the photoresist was polymerized by a 780-nm laser beam. The synthetic brochosome structures were printed by moving the focus point of the laser beam in accordance with the 3D file instructions. Finally, the uncured polymer was removed by immersing the sample in SU-8 developer for 10 min, followed by rinsing with isopropyl alcohol for 2 min.

Metal Deposition: The 3D-printed synthetic brochosomes were conformally sputter coated with a layer of 100-nm nickel using e-beam deposition (Temescal FC-2000, Ferrotec, USA). The temperature of the samples during the deposition process was maintained around 16° C.

Specular Reflection Measurements: The infrared reflection on synthetic brochosomes was measured using a micro-FTIR spectrometer system (HYPERION II, Bruker, Germany). To ensure measurement accuracy, a gold-coated flat mirror was used as the reference surface for calibration.

FDTD Simulations: FDTD simulations of synthetic brochosome arrays were performed in Ansys Lumerical FDTD Solutions. In all simulations, brochosome (single particle or in arrays) is assumed to be made of nickel and supported by a silicon substrate coated with 100-nm-thick nickel. Permittivities of nickel and silicon in both simulations were acquired from the literature (51). The brochosome arrays were illuminated by a plane wave source positioned 45 μm above the arrays. Both the reflective spectra and the light-brochosome interaction processes were captured in the simulations. To obtain the total reflection spectra, the lateral dimensions of the simulation domain were set based on the size of brochosomes (˜20 μm). The lateral boundary conditions in the x- and y-directions were set to be periodic to replicate a 2D infinite array. The boundary condition in the z-direction was set to be perfectly matched layers (PMLs) to absorb all outgoing waves and eliminate unphysical resonances. The total reflection spectra were captured by a 2D frequency-domain field and power monitor placed on the back side of the plane wave sources. To simulate the specular reflection spectra, similar simulation setup as the total reflection simulations was utilized, and the 2D electrical field captured by a frequency-domain field and power monitor is analyzed using the near-to-far field projection function of Ansys Lumerical. The angular distribution of reflected energy was acquired first and then integrated within a cone around the normal direction with a half vertex angle of 20°. The noises of the simulated specular reflection spectra were filtered using the moving average method with a filter window size of 2.5 to 5% of the total number of data points. The simulation videos were captured within one of the brochosomes of the infinite brochosome array. To capture the absorption cross-sections of single brochosomes, the total-field scattered-field source is used to illuminate the brochosome, and the absorbed power was captured and analyzed by “cross section,” a built-in module of Ansys Lumerical, to calculate the absorption cross-section. To capture the light-matter interaction videos of single brochosomes, the brochosome is illuminated by a plane wave source, and the interaction video is captured by a movie monitor located at the central cross-section of the brochosome. Boundary conditions are set to be PMLs to absorb all electromagnetic waves leaving the simulation domain to eliminate unphysical resonances.

### Results

Characteristic Lengths of Natural Brochosomes: In nature, the sizes of brochosomes and their corresponding through-holes exhibit remarkable consistency across different leafhopper species, despite the varying body lengths of leafhoppers ranging from 3 mm to 9 mm (18, 19, 34). Specifically, the majority of natural brochosomes have diameters ranging from approximately 300 nm to 700 nm, while the through-holes measure around 100 nm to 280 nm in size (FIG. 12F). Furthermore, this analysis showed that the ratio between the through-hole size and the natural brochosome diameter consistently approximates 0.28±0.04. This ratio closely aligns with the theoretical value of 0.29 for a buckyball model, or a truncated icosahedron model. These observations indicate a remarkable precision and consistency in the formation of natural brochosomes. However, the relationship between their geometrical characteristics and the antireflection function remains an open question.

The Geometry of a Buckyball or a Truncated Icosahedron: In geometry, a buckyball or truncated icosahedron is one of the thirteen Archimedean solids, including 12 pentagonal faces and 20 hexagonal faces. The edge length, a, of a buckyball follows the following relationship with the diameter D of its circumscribed sphere:

$$D = a \sqrt{1 + 9 {φ}^{2}} \approx 4.96 a \qquad ( EQ . 1 )$$

where φ represents the golden ratio.

In electron scanning microscopy measurements and from the reported data in the literature (1, 2), it was observed that the majority of brochosomes resemble a buckyball-like structure. It is important to note that the edges of brochosomes have finite thicknesses. Specifically, the thickness of the edges (or wall thickness of through-holes) on brochosomes is approximately 7% of the circumscribed sphere diameter, D. Considering these factors, the diameters of inscribed circles of pentagons, dₚₑₙ, and hexagons, dₕₑₓ, on brochosomes can be calculated:

$${d}_{pen} = 0.93 a tan 54 ° \\ {d}_{hex} = 0.93 a tan 60 ° \qquad ( EQ . 2 )$$

and the geometrical mean of dₚₑₙ and dₕₑₓ can be calculated as:

$$d = \sqrt{{d}_{pen} {d}_{hex}} \approx 0.29 D \qquad ( EQ . 3 )$$

Therefore, the geometrical calculation demonstrates that the average size of the pentagonal and hexagonal through-holes on brochosomes is about 29% of the diameter of brochosomes.

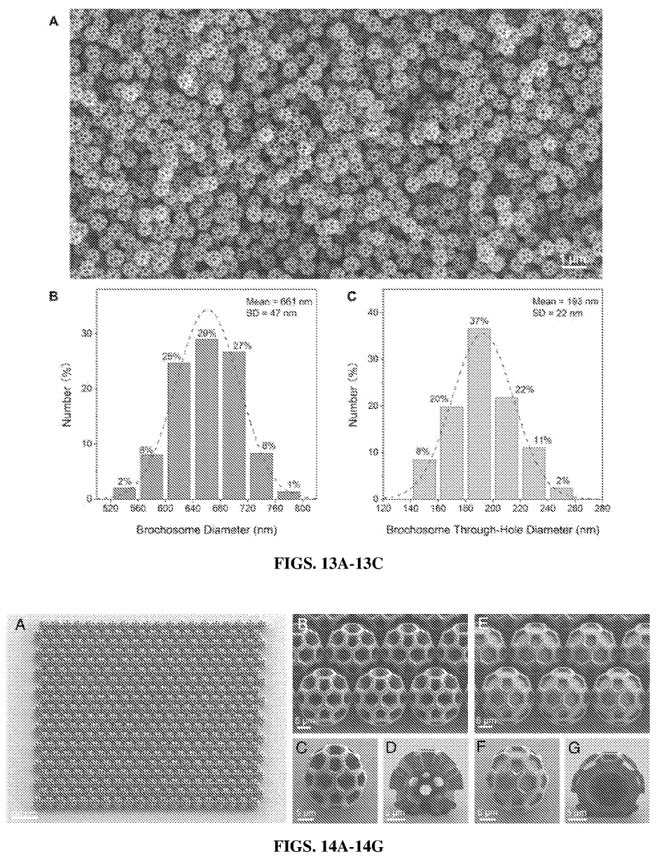

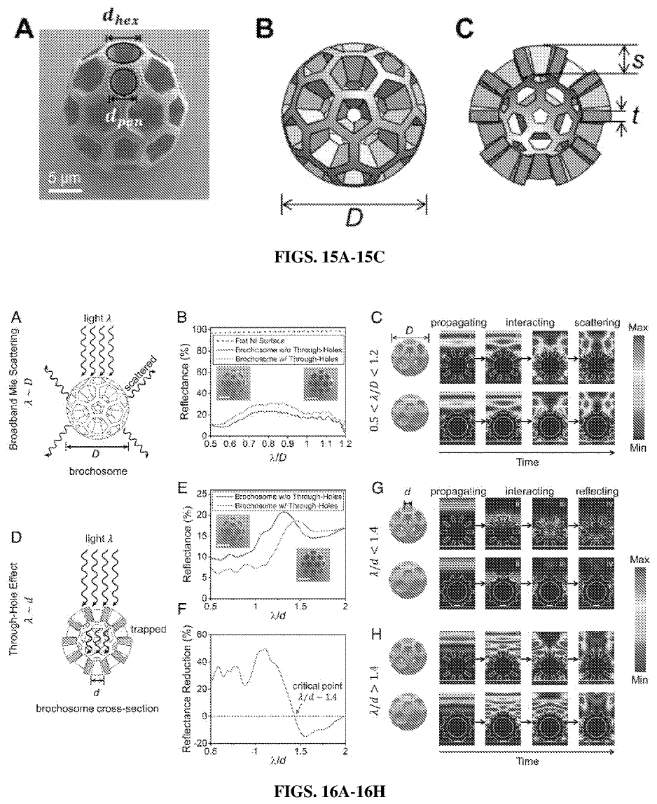

Fabrication of Synthetic Brochosomes: To investigate the geometrical effect of brochosomes on their antireflection performance, the study utilized a two-photon polymerization 3D printing technique to accurately replicate their geometries (FIG. 2). While state-of-the-art 3D printers like the Nanoscribe Photonic Professional can create objects with a resolution of 200 nm to 500 nm, the printing resolution falls short of replicating the nanoscale geometries of natural brochosomes (i.e., ˜300 nm to 600 nm). To overcome this limitation, the study employed a scaling model method, which was previously used in the studies of antireflection properties of nanostructured moth-eye surfaces using longer wavelengths of electromagnetic waves (2). Consequently, the study fabricated microscopic synthetic brochosomes as a model system and examined their optical characteristics in the near-infrared (near-IR) and mid-infrared (mid-IR) ranges (FIGS. 14A-14G and FIGS. 15A-15C). Specifically, the study designed synthetic brochosomes with diameters of approximately 20 μm and through-hole diameters around 5 μm to ensure that the printed structures were significantly larger than the resolution of the 3D printer. The 3D-printed synthetic brochosomes include 12 pentagonal and 20 hexagonal through-holes interconnected by a hollow core, mimicking the precise geometries of natural brochosomes (FIGS. 14B-14D). As shown in FIG. 14A, the fabricated sample includes an array of 20 by 20 synthetic brochosomes in a hexagonal close-packed (HCP) lattice, resulting in a particle packing density of approximately 91%. This arrangement emulates the close packing density of natural brochosomes observed on leafhoppers' wings (FIGS. 12C-12E). The brochosome array covers an area of approximately 400 μm by 350 μm. The shell thickness and through-hole wall thickness of the synthetic brochosomes is approximately 7% and 20% of the overall diameter D, respectively, closely mimicking the characteristics of natural brochosomes (18, 25). As a control sample, the study also fabricated another type of synthetic brochosomes with the same topographical features as their natural counterpart but without through-hole structures (FIGS. 14E-14G).

Design Parameters of Synthetic Brochosomes: As illustrated in FIGS. 15A-15C, the study designed the synthetic brochosomes by closely mimicking the geometrical parameters of natural brochosomes. Based on experimental observations of natural brochosomes reported in the literature (1, 2), it was found that the shell thickness, s, of a natural brochosome is approximately 20% of the overall diameter, D, and the through-hole wall thickness, t, is approximately 7% of the overall diameter D.

Optical Characterizations of Synthetic Brochosomes: Using the microscale synthetic brochosomes as a model system, the study performed specular reflectance measurements in the wavelength range from near-IR to mid-IR (i.e., 2.5 μm<λ<10 μm and 10 μm<λ<24 μm) using a micro-Fourier transform infrared (FTIR) spectrometer. It is important to note that the microscopic dimensions of the synthetic brochosomes minimize the plasmonic effect, as the angular frequency of the incident light in the infrared range is much lower than the typical plasma frequency of metals (˜1015 Hz). To ensure that the materials of the synthetic brochosomes do not contribute to infrared absorption, they were coated with a 100-nm nickel layer, which is a highly reflective metal for infrared light (FIG. 16B). The study confirmed the deposition of the nickel coating on the synthetic brochosomes using energy-dispersive X-ray spectroscopy elementary mapping analysis.

These experimental measurements demonstrated that synthetic brochosomes with through-holes can effectively reduce specular reflection in the wavelength range from 2.5 μm to 24 μm by up to approximately 94% (FIGS. 16A-16H). Specifically, the study observed two distinct antireflection regimes by analyzing the reflection spectra of synthetic brochosomes with and without through-holes. In the first regime, when the wavelength of light is comparable to the diameter of synthetic brochosomes, D, (i.e., ˜0.5≤λ/D≤˜1), but larger than the through-hole diameters, d, a broadband antireflection effect is observed. In this regime, both synthetic brochosomes with and without through-holes exhibit a reduction in reflection of approximately 80% compared to a reflective flat nickel surface (FIG. 16B). In the second regime, when the wavelength of light is smaller than or comparable to the through-hole diameter, d, (i.e., λ/d<˜1.4), the study observed an additional reduction in reflection of up to approximately 53% on synthetic brochosomes with through-holes compared to those without through-holes (FIG. 16E).

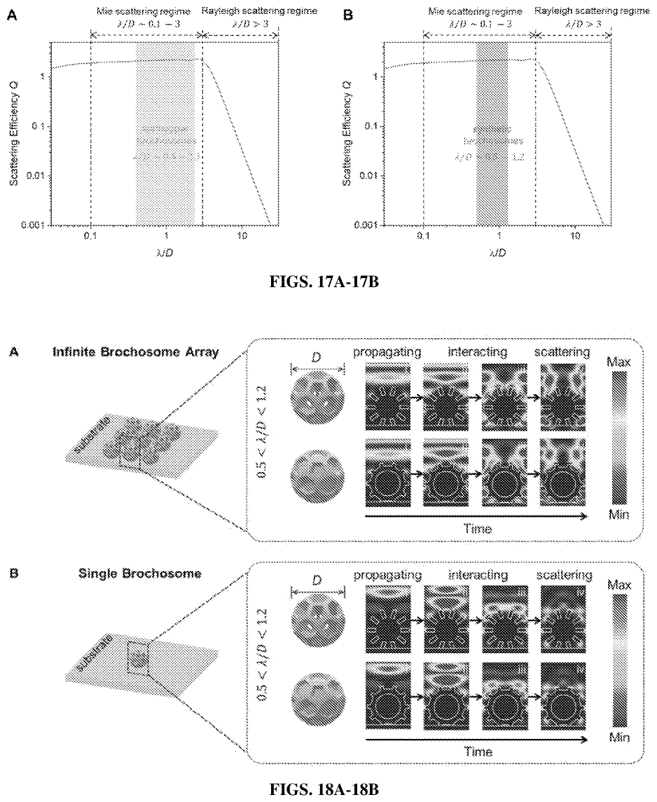

Broadband Antireflection of Brochosomes through Mie Scattering: The broadband antireflection phenomenon in the first regime could be attributed to Mie scattering. Specifically, Mie theory indicates that broadband scattering of light dominates when the particle size is comparable to the wavelength of light (33) (FIG. 16A). Mie's solution outlines that the light scattering efficiency of a spherical particle can be calculated based on the following expression (33, 35):

$$Q = \frac{{λ}^{2}}{{π}^{2} {D}^{2}} {\sum }_{n = 1}^{∞} ( 2 n + 1 ) ( {\vert {a}_{n} \vert}^{2} + {\vert {b}_{n} \vert}^{2} ) \qquad ( EQ . 4 )$$

where the scattering coefficients aₙ and bₙ are defined by Bessel and Neumann functions, and their explicit expressions can be found in the literature (35). In particular, EQ. 4 predicts that the scattering efficiency is maximized when the ratio between the wavelength of light and particle diameter, λ/D, is around 0.1 to 3 (FIGS. 17A-17B). It is important to note that the above analytical relationship (EQ. 4) is developed based on a spherical particle model (33, 35). For more complex particle geometries, such as brochosomes, numerical simulations are necessary to understand their light scattering behaviors, in particular when the light-particle interactions involve multiple particles on a solid substrate (36).

To verify the light scattering process on brochosome arrays, the study first conducted optical simulations using the finite-difference time-domain (FDTD) method and obtained a series of time-resolved simulation videos. A detailed illustration of the simulation set-up is presented in FIGS. 18A-18B. These results showed that the light scattering intensity and patterns on the synthetic brochosome arrays, both with and without through-holes, are nearly identical to each other in the dimensionless wavelength range of ˜0.5≤λ/D≤˜1.2. Time-lapse images of the light scattering process on brochosome arrays are shown in FIG. 16C. For completeness, the study also performed FDTD simulations to illustrate Mie scattering on a single brochosome, both with and without through-holes (FIG. 18B). Light is effectively scattered both on a single brochosome particle and brochosome arrays when the wavelength of light is comparable to the size of brochosome particles (˜0.5≤λ/D≤˜1.2). These simulation results are consistent with the prediction from EQ. 4, demonstrating efficient light scattering on buckyball-shaped brochosomes in this range. Additionally, it was observed that the incident light does not interact with the secondary through-holes within this wavelength range (FIG. 16C). This observation highlights the importance of matching the diameters of the brochosomes with the wavelength of light to facilitate the Mie scattering effect (36).

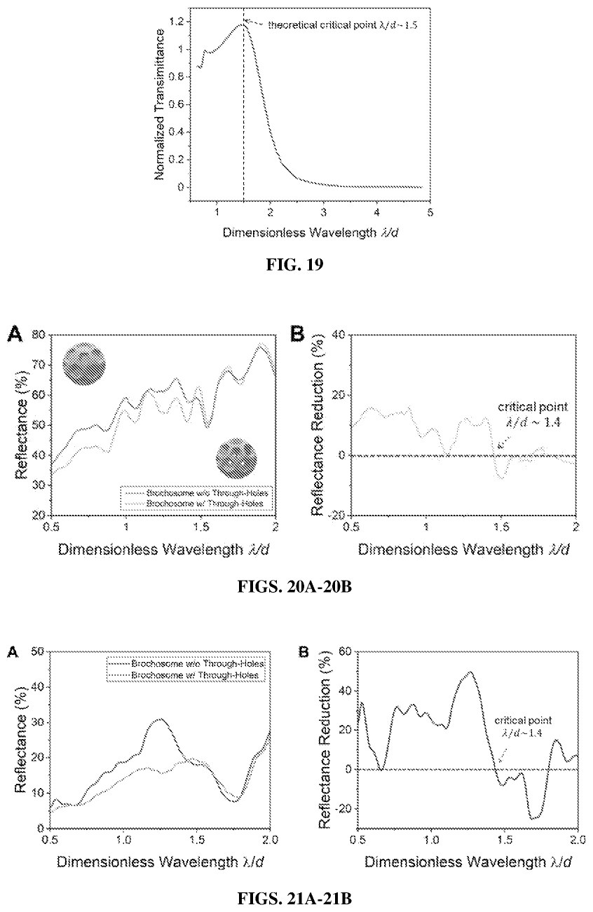

Antireflection of Brochosomes by the Through-Hole Effect: The additional reduction in optical reflection on brochosomes with through-holes could be attributed to the cavity absorption effect enabled by through-holes when the light wavelength is smaller than or comparable to the through-hole diameters (i.e., λ/d<˜1.4) (FIG. 16D). The study performed a theoretical analysis and found that these through-holes could serve as short-wavelength, low-pass filters to further reduce light reflection. Specifically, when considering light interacting with a brochosome, it can be approximated as light passing through a plane with through-holes. According to the classical theory of optics, light cannot pass through a hole whose characteristic size is smaller than the wavelength of light (37). In the 1940s, Bethe derived a simplified expression for the light transmittance of an ideal hole with an infinitesimal thickness (38):

$${T}_{B} ∼ {( \frac{d}{λ} )}^{4} \qquad ( EQ . 5 )$$

where d is the diameter of a through-hole and k is the wavelength of light. EQ. 5 shows that the light transmittance of a through-hole decreases rapidly as d becomes smaller than λ. It has been shown that the light transmittance could be further attenuated for a through-hole when its thickness is increased (39). Recent studies based on Maxwell's equations have demonstrated that when the thickness of a through-hole, h, is equivalent to the radius of a through-hole (i.e., h=0.5d), the critical cutoff wavelength, λ_{c}, above which the light transmittance exponentially attenuates, follows the relationship (40, 41) (FIG. 19):

$${λ}_{c} \approx 1.5 d \qquad ( EQ . 6 )$$

EQ. 6 indicates that when the wavelength of light is greater than 1.5 times the through-hole diameter, most of the light cannot be fully transmitted. Based on EQ. 6, it was hypothesized that the critical wavelength would be approximately 1.5 times that of the through-hole diameter of brochosomes (i.e., λ_{c}/d≈1.5) as it was found that the shell thickness of the majority of natural brochosomes is comparable to the average radius of their through-holes.

These experimental measurements observed a notable reflection reduction on the synthetic brochosomes with through-holes compared to those without through-holes when the wavelength of incident light is shorter than the critical wavelength, λ_{c} (FIG. 16E). To illustrate the geometrical relationship between reduced reflection and through-holes, the study plotted the measured reflection spectra against the dimensionless wavelength, λ/d. As shown in FIG. 16E, the measured reflectance on brochosomes with through-holes ranges from approximately 5 to 18% within the dimensionless wavelength range of approximately 0.5 to 1.4 (corresponding to λ=2.5 μm to ˜7.2 μm). In contrast, the measured reflectance on brochosomes without through-holes is higher, varying from around 10 to 22% within the same range. Particularly in the dimensionless wavelength range of approximately 0.5 to 1.0, where the wavelength of incident light, λ, is smaller than the through-hole diameter, d (i.e., λ/d<1), the reflection on brochosomes with through-holes is further reduced by up to 53% compared with those without through-holes, as shown in FIG. 16F. Notably, the measured critical wavelength is approximately 1.4 times the through-hole diameter (i.e., λ_{c}/d˜1.4), which is in good agreement with the theoretical value of 1.5 predicted by EQ. 6. These measurements indicated that the through-holes play an important role in reducing the light reflection on the brochosomes.

To further elucidate the optical absorption behaviors within the through-hole structures, the study conducted optical simulations using the FDTD method on both individual brochosome particles and brochosome arrays to examine the light-brochosome interaction process in the short-wavelength range (FIG. 16G, FIGS. 18A-18B, FIGS. 20A-20B, FIGS. 21A-21B, and FIG. 22). FIG. 16G shows the captured electrical field profiles obtained from the simulated light-brochosome interaction videos. It was observed that when the wavelength of incident light is shorter than the critical wavelength (i.e., λ<λ_{c}), the light can enter the brochosomes by passing through the through-holes and resonates inside the cavities of brochosomes before being absorbed by brochosomes and dissipated as heat (FIG. 16G, Top). This resonance effect prolongs the interaction time between the brochosomes and light, leading to enhanced light absorption below the critical wavelength λ_{c}. Conversely, when the wavelength of incident light is longer than the critical cutoff wavelength (i.e., λ<λ_{c}), the light cannot pass through the through-holes, and the reflection behavior on brochosomes becomes similar regardless of the presence of through-holes, as shown in FIG. 16H.

In addition to the time-resolved simulations, the study also conducted simulations to analyze the total and specular reflectance spectra of brochosome arrays, both with and without through-holes, in the wavelength range of 2.5 μm to 10 μm (FIGS. 20A-20B and FIGS. 21A-21B). This range corresponds to the same dimensionless wavelength range, from 0.5 to 2.0, as used in the experiments. The simulated spectra further supported these findings: When λ/d is less than approximately 1.4, the reflection on brochosomes with through-holes is further reduced compared to those without through-holes (FIGS. 20A-20B and FIGS. 21A-21B). This result is consistent with both the experimental measurements and the theoretical prediction outlined by EQ. 6.

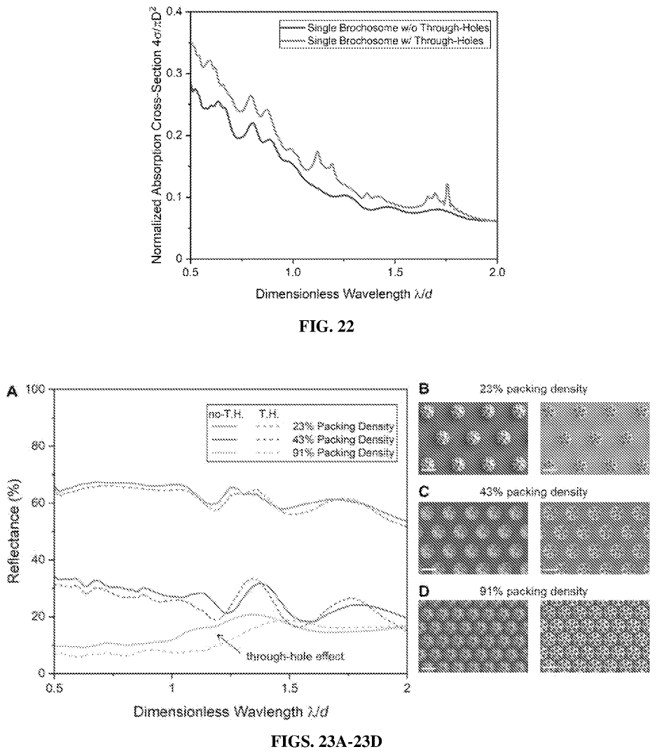

To further demonstrate that the reflectance reduction is due to enhanced light absorption by the through-hole effect, the study simulated the absorption cross-section of brochosomes with and without the through-holes at the single particle level (FIG. 22). Specifically, the absorption cross-section characterizes the ability of the studied particle to absorb light given the illumination condition of the incoming light. If the through-hole effect is present, then notable light absorption by the single brochosome below a certain wavelength may occur. As demonstrated in FIG. 22, a brochosome with through-holes exhibits a greater absorption cross-section than one without the through-hole structure when λ/d is less than or comparable to 1.5. This finding further supports the enhanced light absorption by brochosome with through-holes.

These experimental and simulation results have demonstrated that the specular antireflective properties of brochosomes are contributed by two factors: 1) Mie scattering, resulting from the length scale matching between the diameter of brochosomes and the wavelength of incident light and 2) the through-hole absorption effect, occurring when the wavelength of incident light is smaller than or comparable to the diameter of the through-holes.

Theoretical Prediction of the Critical Cut-Off Wavelength of Light on a Hole with Finite Thickness: Diffraction theory concerning the interaction of light with small holes has been extensively studied, and a number of theoretical frameworks have been reported (3). As predicted by Beth (4), it is challenging for light to pass through a hole whose width is smaller than the wavelength of light. Some studies have attempted to perform rigorous calculations to determine the theoretical cut-off wavelength for a given hole using Maxwell's equations (5-7). Recent studies have specifically demonstrated that the thickness of the hole can further attenuate the transmission of light (5, 7). For example, studies (5, 7) have shown that when the thickness of the hole is equal to the radius of the hole, the transmittance spectrum can be calculated as shown in FIG. 19. It has been observed that the transmission of light begins to notably decrease when the wavelength of light exceeds approximately ˜1.5 times the diameter of the hole.

Size Distribution of Brochosomes and Through-Holes: Through experimental measurements using high-resolution scanning electron micrographs, it was shown that leafhoppers have monodispersed brochosomes with a very narrow size distribution (see FIG. 13A). To further illustrate the monodispersity of natural brochosomes, the study characterized the particle size distribution of natural brochosomes generated by the leafhopper Gyponana serpenta as a representative example. The results are summarized in a histogram in FIGS. 13A-13C. The average diameter of the brochosomes can be estimated by fitting the histogram to a normal distribution function:

$$f ( x ) = \frac{1}{σ \sqrt{2 π}} exp ( - \frac{{( x - D )}^{2}}{2 {σ}^{2}} ) ,$$

where D is the average diameter and σ is the standard deviation. It was found that the majority of the measured brochosomes have an average diameter of approximately 661±47 nm. These results demonstrate that natural brochosomes are monodisperse with a coefficient of variation (i.e., σ/D) of approximately 7.2%. The study also characterized the size distribution of through-holes in 300 natural brochosomes. As shown in FIG. 13C, the average diameter of the through-holes is 193±22 nm, with a coefficient of variation of approximately 11.5%. Notably, about 79% of through-holes have a diameter in the range of 160 nm to 220 nm. It is important to note that natural brochosomes consistently exhibit a buckyball-like geometry. This geometry ensures a consistent ratio of approximately 29% between the through-hole size and the brochosome diameter, which aligns well with these measurements (i.e., 193 nm/661 nm≈29%).

Packing Density of Brochosomes: The study defined the packing density of particles on a 2D plane by normalizing the total projected area of particles to a unit area. Specifically, the packing density can be expressed as

$$η = \frac{π {D}^{2}}{2 \sqrt{3} {H}^{2}} ,$$

where D is the diameter of brochosomes and H is the side length of the unit cell. In a hexagonally close-packed (HCP) arrangement, the packing density is approximately 91%. The critical packing density, η_{c}, above which the through-hole effect is more prominent, is approximately 58% in a hexagonal packing arrangement when the inter-particle spacing is about 5 μm (i.e., the size of the through-holes in this setup). To test the robustness of the through-hole effect against packing density, the study fabricated a series of synthetic brochosome arrays, both with and without throughholes, arranged in a hexagonal packing density of 91%, 43%, and 23%. The experimentally measured specular reflectance shows that the through-hole effect is more evident when the brochosomes are densely packed (i.e., when the packing density exceeds f_{c}), as demonstrated in FIGS. 23A-23D. In contrast, the through-hole effect becomes less pronounced as the packing density falls below f_{c}.

In addition, by counting the number of observable brochosomes within a defined unit area in a high-resolution electron micrograph (see FIGS. 13A-13C), the study estimated that the packing density of brochosomes on the leafhopper wings is approximately 84%, which is greater than η_{c}.

### Discussion of the Similarities and Discrepancies Between Simulation and Experiment:

### Similarities:

1. Critical cutoff wavelength for the through-hole effect: All the experimental results, along with simulated results for both total and specular reflectance, demonstrate that the cutoff dimensionless wavelengths, below which through-hole effect is most dominant, occur at ˜1.4. These findings closely align with the theoretically predicted value of ˜1.5 (EQ. 6, FIG. 19).
2. Reflectance reduction below the cutoff wavelength: The experimentally measured specular reflection data shows that the reflectance reduction below the cutoff wavelength is up to ˜50% (FIG. 16F). This is in good agreement with the simulated specular reflectance results, which show a reduction of up to ˜50-55% (FIGS. 21A-21B).

### Discrepancies:

1. FDTD simulation for total reflectance: For the comparison of the overall magnitudes between the experimental and simulated total reflectance spectra, the magnitude of the simulated total reflectance spectra in FIGS. 20A-20B is higher than that of experimental measured spectra in FIG. 16E. This difference primarily stems from the challenges in precisely matching the exact experimental conditions with simulation parameters. Specifically, the simulated spectra in FIGS. 20A-20B represent the total reflection data collected from an infinite 2D brochosome arrays, achieved by periodic boundary conditions in FDTD simulations. To experimentally match such simulated spectra, an integrating sphere in the infrared range compatible with an FTIR microscope is required. However, there is no commercially available integrating sphere that is compatible with an FTIR microscope to perform total (or diffuse) reflectance measurement. Consequently, the experimental reflection spectra in FIG. 16E were measured using an FTIR microscope without an integrating sphere, resulting in specular reflection measurements within an angle of 0-17 degrees deviated from the vertical direction.
2. FDTD simulation for specular reflectance: While the magnitudes of the simulated specular reflectance spectra match those of the experimentally measured specular reflectance data, it is important to note that there are still some discrepancies in magnitudes between these simulated and experimental spectra. This is due to the challenges inherent in fully replicating the experimental conditions in simulation models. In the experiment, the brochosome array is finite, and only those brochosomes within the aperture of micro-FTIR instrument are illuminated and measured. In contrast, the array-level simulation assumes an infinitely large 2D array, illuminated by a linearly polarized plane wave source with a well-defined wavefront. Furthermore, the FDTD simulations software Ansys Lumerical utilizes a structured mesh of ˜100 nm, where the simulation domain is discretized into rectangular grids in x, y, and z directions. This presents additional challenges to fully capturing the spherical, curved nature of brochosomes in the simulations.

### Discussion

Geometrical Consistency of Natural Brochosomes: These observations reveal that both the diameters of the brochosomes and their through-holes consistently fall within the range of hundreds of nanometers across different leafhopper species, showing weak dependence on leafhopper body length, as shown in FIGS. 24A-24B. Importantly, it was found that the ratio between the diameter of natural brochosomes (˜300 nm to ˜700 nm) and the wavelength of UV-visible light (˜300 nm to ˜700 nm), ranges from ˜0.4 to ˜2.3. This places them within the effective Mie scattering regime for UV-visible light, as depicted by EQ. 4 (FIG. 24A and FIGS. 17A-17B). Furthermore, it was observed that the through-hole sizes (˜100 nm to ˜280 nm) fall within the range that can effectively reduce UV light reflection, as depicted by EQ. 6 (FIG. 24B). These findings suggest that the diameters of natural brochosomes and their corresponding through-hole sizes may have evolved to effectively reduce light reflection in both the visible (˜400 nm<λ<˜700 nm) and UV (˜300 nm<λ<˜400 nm) range.

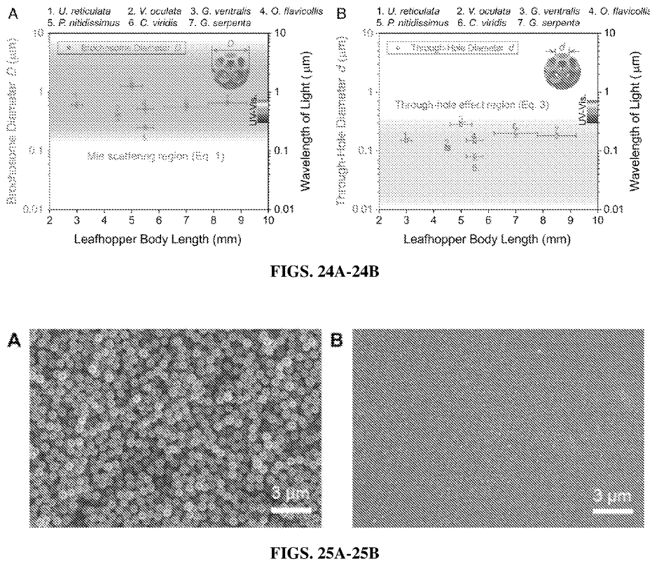

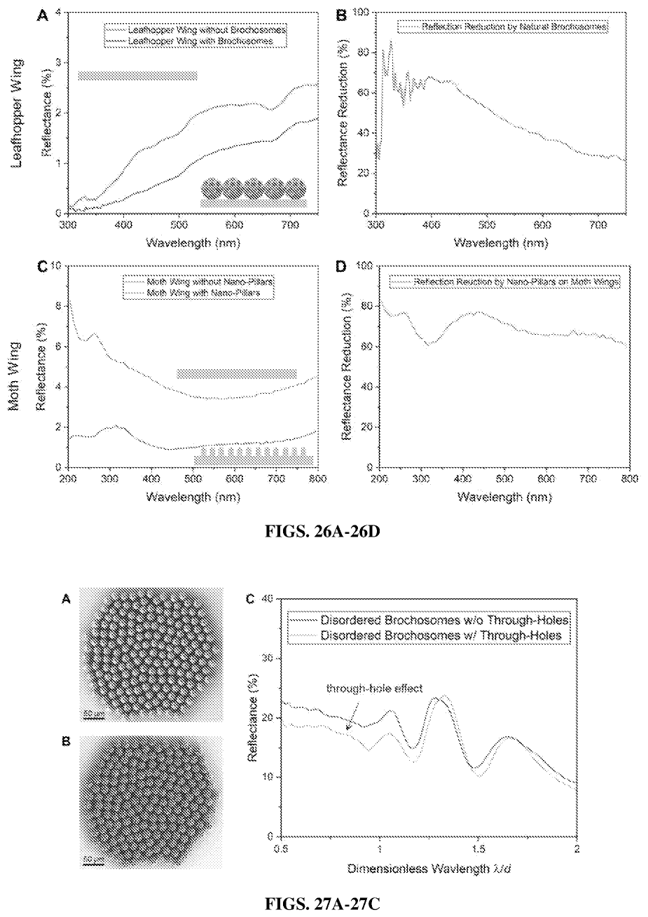

To validate these analyses on biological samples, the study measured the specular reflection on leafhopper wings, both with and without brochosomes (FIGS. 25A-25B and FIGS. 26A-26D), to gain qualitative insights into the antireflection performance. It is important to recognize that directly validating the geometry-induced antireflection mechanisms on biological samples could be complicated by the light-absorbing properties of the materials including the leafhopper wing and brochosomes, particularly when the wavelength of light is less than 300 nm (44). These measurements show that the specular reflection on a leafhopper wing coated with brochosomes can be reduced by ˜28 to ˜86% in the UV range (i.e., ˜300 nm<λ<˜400 nm), and by ˜28 to ˜68% in the visible light range (˜400 nm<λ<˜700 nm), compared to a bare leafhopper wing without brochosomes (FIGS. 26A-26D). This degree of reflection reduction is comparable to that observed on moth wings with nano-pillars, which show an average reduction of approximately 69% compared to a bare moth wing without nano-pillars (FIGS. 26A-26D). In the case of the leafhopper wing, the observed reduction in broadband UV-visible reflection is consistent with the results derived from synthetic brochosomes, where the combined through-hole effect and Mie scattering significantly reduce UV reflection, and Mie scattering alone contributes to broadband anti-reflection in the visible light range.

In addition, natural brochosomes are typically found densely packed in a disordered arrangement (FIG. 12C). To understand how the packing density and disorderliness of brochosomes affect light reflectivity, the study conducted further experiments using synthetic brochosomes. It was found that the through-hole effect becomes more pronounced when the packing density exceeds the critical packing density η_{c}, which is approximately 58% (FIGS. 23A-23D). This effect is particularly noticeable when the gap distance between individual particles is smaller than the through-hole diameter. Additionally, the study also performed a disorder analysis to examine the robustness of the through-hole effect. The study fabricated synthetic brochosomes, both with and without through-holes, and arranged them in a disordered array (FIGS. 27A-27C). These experimentally measured specular reflectance reveals that the through-hole effect remains evident in a disordered arrangement (FIGS. 27A-27C).

Biological Implications: How do antireflective brochosomes benefit leafhoppers? Antireflective surfaces are commonly found across the insect kingdom, with some of the well-known examples being the moth's eye (2) and insect wings (45). It has long been hypothesized that these antireflective surfaces help insects by reducing mirror-like reflections, thus providing camouflage or decreasing their detectability to predators (46). Similarly, it was hypothesized that leafhoppers consistently apply a dense coating of brochosomes on their wings, potentially maximizing the surface anti-reflectivity to avoid attracting predators with mirror-like reflected light. To maintain a high packing density, leafhoppers frequently secrete and distribute brochosomes across their body surfaces. They engage in anointing and grooming behaviors every few hours, ensuring a multilayered, dense, and evenly distributed brochosome coating on their bodies (47). These behaviors, observed in both nymphs and adult leafhoppers, persist throughout their lifespan (47).

The predators of leafhoppers, such as birds and lizards, possess tetrachromatic color vision, which enables them to perceive an extended range of colors, including UV colors (42, 48, 49). Plant leaves, which are a common habitat of leafhoppers, contain pigments that can absorb UV light, resulting in reduced UV reflection (50). These results suggest that leafhoppers potentially utilize the through-holes on brochosomes to further decrease UV reflectance, thereby mimicking the low UV reflection of plant leaves. The combined effects of UV absorption by the through-holes and the scattering of visible light by the primary structures of brochosomes could synergistically aid leafhoppers in reducing their observability to predators. While this hypothesis remains to be tested in field studies, these results provide a physical basis for understanding why the size of brochosomes from various leafhopper species may have evolved within a size range on the order of a few hundreds of nanometers. These findings potentially suggest an evolutionary design strategy by leafhoppers, employing highly engineered, deployable optical materials as a means to evade their predators.

### Conclusion

In summary, this study has fabricated high-fidelity synthetic brochosomes using the two-photon polymerization 3D printing method and demonstrated that the hierarchical structures of brochosomes can effectively reduce light reflection through both Mie scattering and through-hole absorption effects. Brochosomes are biological structures that exhibit both short-wavelength, low-pass optical absorption and broadband antireflection functions. Inspired by the intricate 3D architecture of brochosomes, it is anticipated that synthetic brochosomes could lead to the development of a class of bioinspired optical materials capable of interacting with a broad range of electromagnetic spectrum. Potential applications include omnidirectional antireflective coatings, light-absorbing materials, optical encryption, and multispectral camouflage.

### Example 5—Brochosome-Inspired Binary Metastructures for Pixel-by-Pixel Thermal Signature Control

Infrared radiation from objects determines their thermal signatures. Because of the incoherent, isotropic, and broadband characteristics of thermal radiation from bulk materials, precisely engineering thermal signatures, including directional (1, 2) and spectral (3, 4) control by metastructures, is critical for a wide range of energy management and conversion technologies, such as thermophotovoltaics (5-7), radiative cooling (8-11), and smart windows (12). Meanwhile, the wide bandwidth and imperceptibility to human ocular system of thermal infrared light have enabled applications in optical security, camouflage, and encryption. With carefully designed boundary conditions (13), the isothermal contours of heated metal plates, and thus the location-dependent thermal radiation, can be manipulated to encrypt letters or patterns for viewing under infrared cameras only, which are covert in the visible range. However, thermal cross-talk between the hot and cold regions due to the diffuse heat conduction hampers the miniaturization of temperature-based spatial control of thermal signatures. To overcome this drawback, by leveraging the scattering fields from nanostructures (14-16), metasurfaces have been designed to tailor (infrared) wavefronts to reveal the concealed patterns and images when illuminated by lasers. Nevertheless, the requirement of external laser sources limits their applications. While advancements have been made in spatial modulation of emissivity, via phase-change materials (17, 18), nanostructured plasmonic materials (19, 20), and gated graphene (21), a universal and systematic solution for heat-driven, microscale thermal signature control is still lacking.

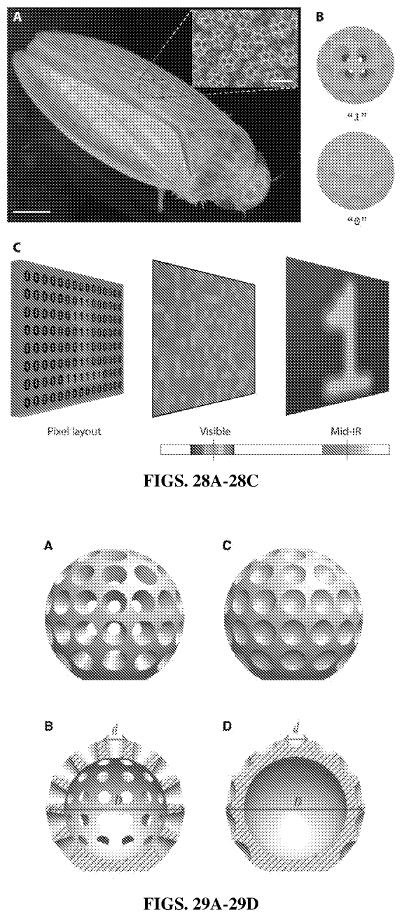

Inspired by leafhopper-produced brochosomes (FIGS. 28A-28C and inset), here, a study was conducted which introduced an infrared signature management solution by pixelating surfaces with a spatial resolution down to the micrometer level with a pair of microsized pixel twins. Brochosomes are hollow spherical structures with distributed open pores interconnected by a hollow cavity (22-25). On the basis of the brochosome-inspired pixel twins, the study demonstrated a dual effect of concealing binary information/images in the visible range but displaying them in the infrared range via thermal excitation, without relying on external light sources such as lasers. To mimic the binary states in digital electronics, these brochosome-like pixel (BLP) twins are engineered with either open pores (op-BLPs; FIG. 28B, top) or closed pores (cp-BLPs; FIG. 28B, bottom) and perform as the building blocks for spatial emissivity manipulation. As illustrated in FIG. 28C, BLP twins show distinct emissivities when thermally excited, which form infrared counterparts of the binary states 0 and 1. Therefore, images can be encoded using a “bitmap” including the pixel twins, which can then be visualized using infrared imaging systems. This pixel-by-pixel approach uses the unique brochosome geometries, instead of specific material property for emissivity control, and thus is compatible with different substrates. The two types of BLPs share similar appearances when observed under visible imaging systems. This similarity allows the stored patterns formed by one type of BLPs to blend with the background formed by the other. This effect resembles “background matching,” a common camouflage strategy in nature (26, 27). This pair of microscopic structures has been designed to be distinguishable in the infrared range, while remaining indistinguishable in the shorter visible range, despite the fact that the shorter wavelength typically provides a finer spatial resolution, according to the Rayleigh criterion.

### Materials and Methods

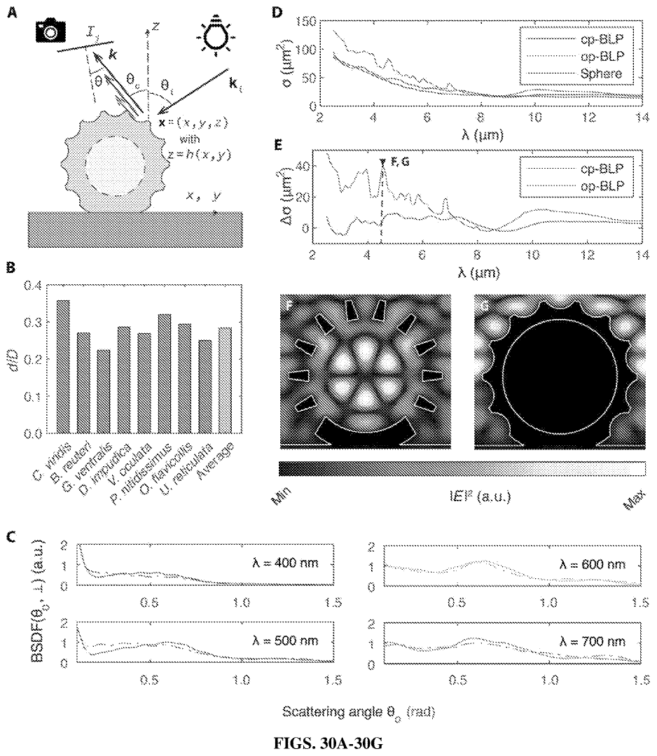

Design and modeling of BLPs: The design and 3D modeling of BLPs are conducted in SolidWorks, a computer-aided design software. The designed structures are then exported as standard triangle language files (.stl) for optical simulations and fabrications. The 3D and cross-sectional views of both a BLP with op-BLP and with cp-BLP are shown in FIGS. 29A-29D, respectively. Each BLP has six loops of pores evenly distributed among the surface. Each loop contains from top to bottom, 1, 6, 10, 14, 14, and 10 pores, respectively. The diameter of pores d and the diameter of BLPs D (shown in FIG. 29B and FIG. 29D) are the key design parameters. The study started the design by adopting the ratio d/D=0.28, which is the average value acquired from natural brochosomes generated by various leafhoppers (FIG. 30B), and then optimized such ratio for best wavelength-dependent distinguishability between the two BLPs (FIGS. 36A-36B). The actual size of the BLPs is designed to ensure strong infrared contrast between the two structures within the entire working wavelength range of the infrared imaging systems (2.5 to 4.2 m). Results shown in the Results section are achieved with BLPs with D=20 μm and d=3.7 μm.

FDTD simulation of BLPs: The FDTD simulations of the BLPs were conducted in Ansys Lumerical FDTD Solutions with the .stl files generated by SolidWorks. The diameter of single BLPs is scaled to 20 μm. The material of the BLPs is set to nickel (Ni); a silicon (Si) substrate (the blue block in FIG. 28A), coated with 100-nm-thick Ni, is also considered in simulations. Both the materials are characterized by their permittivities, which are acquired from (41).

In the simulations of absorption cross section a of single BLPs, the total-field scattered-filed source is used to excite the BLPs, and a is calculated by a built-in analysis module, absorption analysis group, of the software. To generate the field profiles, single BLPs are excited by a plane wave source linearly polarized along the x direction and propagating along the z direction, and a frequency-domain field profile monitor is used to capture the field profiles at the central cross section of the BLPs parallel to the z axis (see FIG. 28A for the coordinate system). Perfectly matched layers (PMLs) are used in both simulations as boundary conditions to remove unphysical echoes. For the simulations of scattering distribution function of the BLPs, a plane wave source (polarized along the x direction and propagated along the z direction) with Gaussian profiles is used to illuminate single BLPs, and a 80-μm by 80-μm 2D power monitor parallel to the x-y plane located 13.5 μm away from the center of the BLPs is used to captured the Poynting vectors of the scattered field, which are then projected to the far field through the built-in module, far-field projection, of the software to calculate the angular distribution. In the simulations regarding the spectral-directional absorptivity (SDA) of BLP arrays, the plane wave source with the type of “broadband fixed angle source technique” is used to illuminate one unit cell. The boundary conditions at directions transverse to the source propagation direction are handled by the software, and the rest boundary conditions are set to PMLs. To be comparable with unpolarized thermal absorption/emission, simulated SDAs shown in FIGS. 34A-34F are averaged over both the S and P polarization states. Then, the averaged SDAs are integrated to calculate the overall emissivity (30)

$$ε = \frac{1}{A B} {\int }_{{λ}_{min}}^{{λ}_{max}} d λ {\int }_{0}^{{θ}_{max}} {ε}_{λ , θ} sin θ cos θ {E}_{λ , b} ( λ , T ) d θ where \qquad ( EQ . 7 )$$

$$A = {\int }_{0}^{{θ}_{max}} sin θcosθ d θ \\ and \qquad ( EQ . 8 )$$

$$B = {\int }_{{λ}_{min}}^{{λ}_{max}} {E}_{λ , b} ( λ , T ) d λ \qquad ( EQ . 9 )$$

in which E_{λ,b}(λT) represents the blackbody radiation. θₘₐₓ, λₘᵢₙ, λₘₐₓ, and T are set to 10°, 2.5 μm, 4.2 μm, and 323.15 K, respectively, to match with the specifications of the thermal mapping system used in measurement.

Fabrication of BLPs: The BLP arrays were fabricated by two-photon polymerization 3D printing method using the 3D files of BLPs (.stl) designed in SolidWorks. The 3D printing process was executed by a 3D printer Nanoscribe, with a resolution of 200 to 500 nm. Specifically, the photoresist IP-Dip of about 50 μL was added onto a silicon substrate (p-type/boron-doped [symbol] 100 [symbol] , a resistivity of 1 to 5 ohm-cm; Purewafer, USA), and the photoresist will be polymerized by a laser beam of 780 nm. The BLP structures were printed, while the focus point of the laser beam moves spatially as directed by the 3D modeling file. Last, the uncured polymer was removed by immersing sample into the SU-8 developer for 10 min, and then the sample was rinsed with isopropyl alcohol for 2 min. After that, a 100-nm-thick nickel layer was deposited to the 3D printed BLPs with the electron beam evaporator (Temescal FC-2000, Ferrotec, USA). The temperature of the samples during the deposition process was maintained around 289.15 K (16° C.).

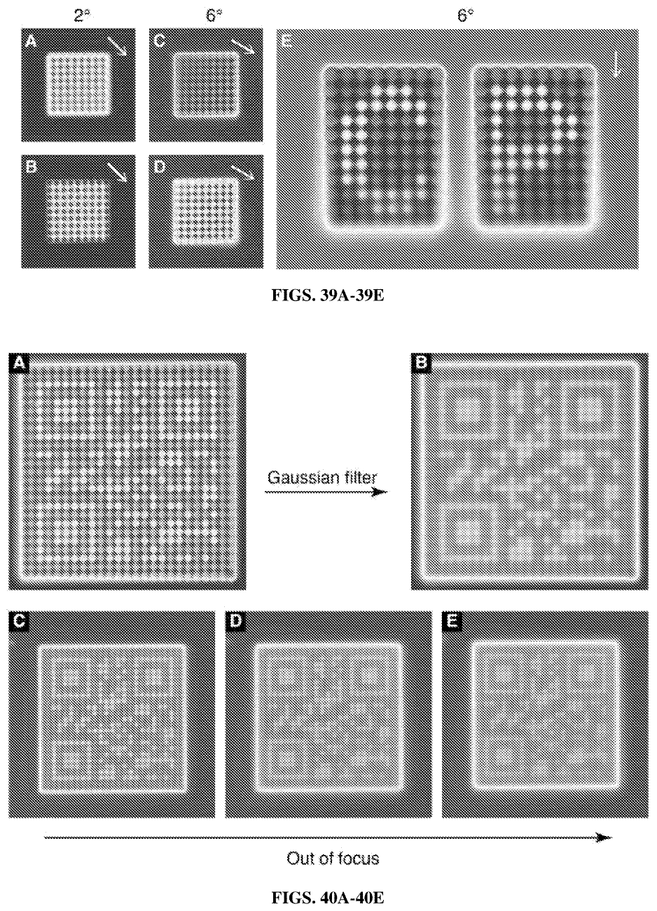

Characterization of BLPs: The morphologies of the fabricated BLP samples are examined under an SEM (Merlin, Zeiss, Germany) for quality control. The infrared images are taken by the thermal mapping system (QFI InfraScope) with a ×20 magnification objective (×12 for the QR code sample unless otherwise specified, thermal stability analysis shown in FIGS. 38A-38G, and the tilted measurement shown in FIGS. 39A-39E). The thermal mapping system captures the infrared emission from the samples within the wavelength range from 2.5 to 4.2 μm and normalizes it to the blackbody emission to calculate the emissivity. During the infrared imaging process, the BLP samples are heated to 323.15 K (50° C.) by a Linkam HFS600 thermal stage, unless otherwise specified in the thermal stability analysis shown in FIGS. 38A-38G. The infrared reflection spectrum of the two samples shown in FIG. 32B are measured by the Fourier transform infrared microscope (Nicolet Continuum). Note that because of the spherical shape of BLPs, the reflected light is distributed in the upper hemispherical space, so the majority of which cannot be received by the Fourier transform infrared system, resulting in the extremely low measured reflectivity. So, it cannot be used to estimate the absorptivity/emissivity of the structure.

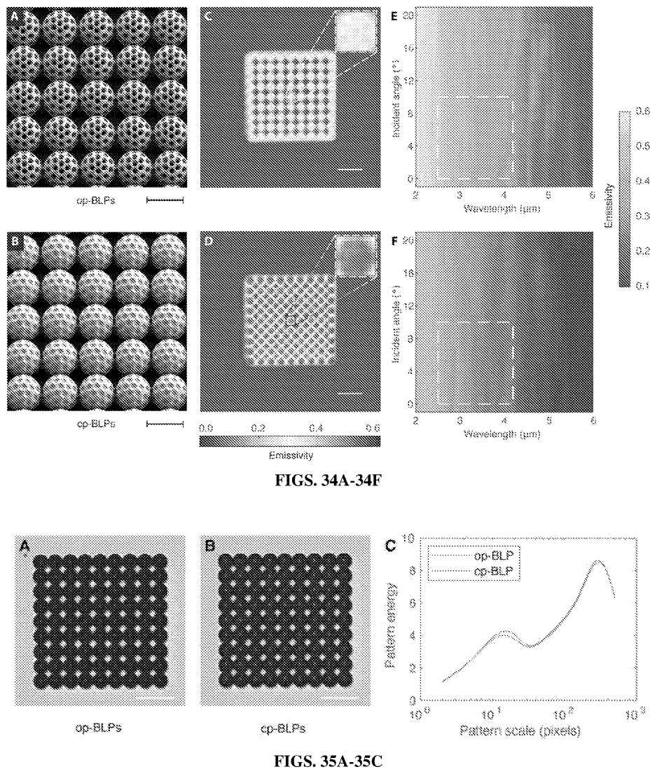

The optical images of the BLP arrays were taken by Nikon digital sight DS-Fil with a ×20 magnification objective (×10 for the QR code sample). The similarity/indistinguishability of the images of different BLP arrays is assessed by the quantitative color and pattern analysis method (33), implemented in the Mica Toolbox. Specifically, images of both the op-BLP and cp-BLP (FIGS. 35A-35B) arrays discussed in FIGS. 34A-34F were captured with the same illumination, and camera settings are imported to the software, where the significance/notability (measured in pattern energy) are analyzed for features of different sizes (measured in pixel) in the images. FIG. 35C compared the pattern energy distribution of the two images, which overlap with each other, indicating a high degree of similarity between them to human eyes.

### Results

BLPs enabled visible camouflage and infrared display: The total irradiance (L) from a BLP reaching the image plane of an imaging system determines its appearance (28-30), and therefore engineering total irradiance in different wavelength ranges is crucial for the design of BLPs. The total irradiance can be expressed as

$$L ( x , k ) = \int \int {f}_{s} ( x , {k}_{i} , k ) {L}_{i} ( x , {k}_{i} ) cos {θ}_{i} dx + {L}_{e} ( x , k ) \qquad ( EQ . 10 )$$

where L(x, k) represents the total irradiance from the location x on the surface of a BLP with a wave vector k (see FIG. 30A for notations). In EQ. 10, the first term on the right-hand side represents the scattering of the BLP (blue arrow in FIG. 30A) with respect to the light source Lᵢ(x, kᵢ), and the surface integration encompasses the illuminated surface of the BLP. fₛ(x, kᵢ, k) is the bidirectional scattering distribution function (BSDF) that characterizes the scattering behavior. The second term, Lₑ(x, k), accounts for thermal emission from the BLP (red arrow in FIG. 30A), which mainly occupies the infrared spectrum when the BLP is thermally excited to a temperature slightly above room temperature, based on Wien's displacement law. In the visible range, EQ. 10 is dominated by the scattering term due to the negligible contribution from emission, while the emission term Lₑ(x, k) reveals the key electromagnetic behaviors of BLPs in the infrared range. To facilitate the short-wavelength camouflage and long-wavelength display, it is desired that the two types of BLPs exhibit similar visible scattering while having distinct infrared emission. To demonstrate this, the study performed finite-difference time-domain (FDTD) simulations for op-BLPs and cp-BLPs in both the infrared and visible ranges (see Materials and Methods). The diameters of pores (d) and BLPs (D) (see FIG. 29B and FIG. 29D) are the key design parameters. The study started the design process by adopting the ratio d/D=0.28, which is an average derived from natural brochosomes (31) produced by diverse leafhoppers, as shown in FIG. 30B. Subsequently, the ratio was optimized to achieve the desired camouflage and display functions, and then the size of BLPs can be chosen according to the target working wavelengths. Here, the diameter D and pore size d of BLPs are set to be 20 and 3.7 μm, respectively, for infrared measurements (see Materials and Methods). The material of BLPs is chosen to be nickel (Ni) or other reflective metals, which provide a high-permittivity contrast between the BLPs and the environment.

In the visible range, the study simulated the BSDFs of both types of BLPs to demonstrate their scattering behaviors. Conventionally, determining BSDF(θₒ, θᵢ) requires the simulations/measurements of the energy distribution at any given scattering angle θₒ with respect to illuminations from various directions θᵢ, as marked in FIG. 30A. Given that optical microscopies used for observing microscale BLPs usually have illuminations primarily from the vertical direction, the study limited the visible-range simulation of the BLPs to the scattering distribution functions with respect to the normal illumination only, i.e., BSDF(θₒ, ⊥). In FIG. 30C, the study compared the simulated results for both op-BLPs (solid lines) and cp-BLPs (dashed lines) at various visible wavelengths. The similarity of BSDFs between the two types of BLPs can be attributed to the identical arrangement (20, 32) of surface features (either open pores or closed pores). These similar BSDFs ensure that the pixel twins cannot be easily distinguished under visible imaging systems, thereby establishing an effective visible camouflage effect.

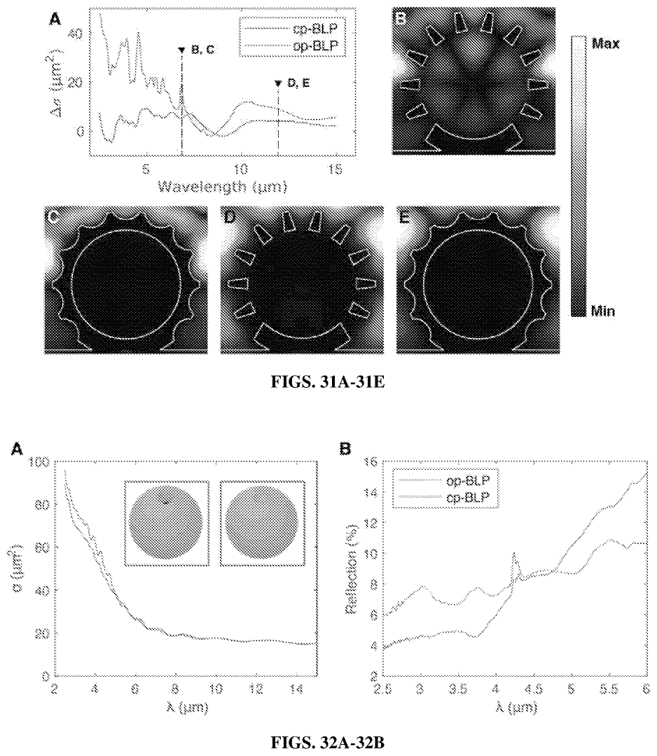

In the infrared range, the study calculated the spectral absorption cross sections (σ) for both types of BLPs. The magnitude of σ also indicates the emission capability of the two structures, based on Kirchhoff's law (30). FIG. 30D showed the results for a single op-BLP and cp-BLP. For comparison, the study included the results for a Ni sphere with the same diameter (20 μm). Within the wavelength range from 2.5 to 8 μm, the op-BLP shows an enhanced absorption cross section, compared to those of the cp-BLP and the sphere. The contrast of a between the op-BLP and cp-BLP structures can be further illustrated in FIG. 30E, where their excess absorption cross section (Δσ=σ_{BLP}−σₛₚₕₑᵣₑ) was plotted relative to that of the sphere. Such an absorption contrast between the BLP twins occurs in a broad wavelength range overlapping with the dominant wavelength of thermal radiation at a temperature slightly above room temperature and thus only requires thermal excitation to be detected. This characteristic differentiates BLPs from other plasmonic metasurfaces, which require external laser illumination. The enhanced σ of the op-BLP within this wavelength range can be explained by the exposed cavity formed by its open pores. As shown in FIGS. 30F-30G, the electromagnetic field penetrates the op-BLP (FIG. 30F), becomes trapped within the exposed cavity, and eventually gets absorbed because of the electron damping effect of Ni. Conversely, this cavity effect remains absent in the cp-BLP (FIG. 30G), which results in the contrast of a between these two structures. Note that such a high contrast gradually decreases after it reaches the maximum at the wavelength around 5 μm because the long-wavelength electromagnetic waves cannot penetrate BLPs even with the existence of the open pores (FIGS. 31A-31E). Therefore, as a general design principle, one can tune the diameter of the open pores (the diameter of the closed pores also needs to be tuned accordingly to ensure the similar visible appearances between the two types of BLPs) to optimize the BLPs for the targeted working wavelength range. By choosing the metal coatings with different damping rates, the contrast between the two types of BLPs can be further engineered. In addition, the unique multipore configuration of BLPs is crucial to achieve the high contrast because simple spherical structures with fewer or single open pore will substantially reduce the amount of light reaching the cavity, thus leading to diminished absorption cross sections (FIG. 32A).

Similarity between BSDFs of the BLP twins: The similarity between the BSDFs fₛ(x, kᵢ, k) of the BLP twins can be understood from the derivation provided by Jos Stam (32) in which the refraction effect is considered. It has been shown that,

$${f}_{s} ( x , {k}_{i} , k ) ∝ 〈 {\vert P ( {k}_{x} , {k}_{y} ) \vert}^{2} 〉 \\ where \qquad ( EQ . 11 )$$

$$P ( u , v ) = [ p ( x , y ) ] = [ {e}^{i k ω h ( x , y )} ] \qquad ( EQ . 12 )$$

in which [symbol] represents the Fourier transform. h(x,y) characterizes the surface morphology of BLPs. As shown in FIG. 30A, for each point x on the outer surface of BLPs with a Cartesian coordinate (x, y, z), the z-coordinate (local height) can be nominally expressed as a function of x- and y-coordinate, namely z=h(x, y). Here h(x, y) will fully capture the morphology of the top half of a BLP (only the top half contributes to the visible appearances of BLPs because the bottom half is blocked and not in direct exposure to the environmental illumination). In both types of BLPs, it is apparent that h(x, y) of both types of BLPs will be similar everywhere except for the open region inside the open pores of op-BLPs due to the same pore size and pore arrangement of the BLPs (regardless of whether the pores are open or closed). EQ. 11 and EQ. 12 show that the Fourier transform of the height profiles, and thus the spatial arrangement of the surface features determines the BSDFs of the BLPs, and consequently their visible region images. Therefore, by keeping the spatial arrangement and the diameter of the pores the same while designing different BLPs, one can ensure that they share similar appearances under the same illumination condition in a visible range imaging system, even though the detailed surface morphologies are different.

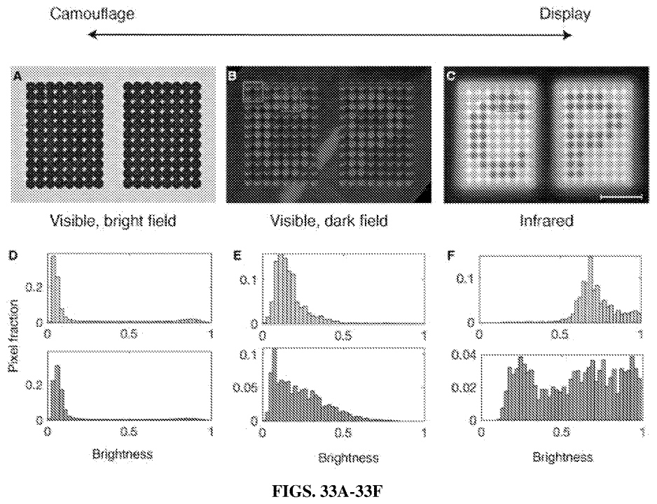

Reduced similarity between BLP twins under visible dark-field imaging systems: The BLP twins show a reduced similarity in dark-field optical images compared to the bright-field ones, as shown in FIGS. 33A-33F, which is mainly due to the slight deviation in their BSDFs, as shown in FIG. 30C. The working principle of a dark-field imaging system is to use a dark field patch stop to block out the specular reflected light (or directly transmitted light in the transmission microscopy setup) so only scattered light enters the objective lens. Therefore, the information carried by the scattering behavior can be enhanced so that such the small deviation between the BSDFs of the two types of BLPs can be amplified, leading to a reduced similarity under a dark-field optical microscopy.

Thermal-optical characterization of BLPs: To quantify the emission contrast, the study fabricated arrays of both cp-BLP and op-BLP and measured their spatial distributions of emissivity using an infrared thermal mapping system (see Materials and Methods). In FIGS. 34A-34B, both the nine-by-nine BLP arrays were fabricated using the two-photon polymerization three-dimensional (3D) printing and subsequently coated with ˜100 nm of Ni. The thickness of the Ni coating is more than two times of its skin depth

$$( {δ}_{e} = \frac{λ}{2 πIm ( \tilde{n} )} \approx 40 nm ,$$

where Im(ñ) represents the imaginary part of the refractive index) within the working wavelength range of the infrared imaging system (see Materials and Methods), ensuring efficient shielding of electromagnetic waves. Consequently, the cavity effect is pronounced only for op-BLPs. FIGS. 34C-34D plot the spatial distributions of the measured emissivity for the op-BLP and cp-BLP arrays, respectively, from which the spatially averaged emissivities were calculated on the basis of the central seven-by-seven BLPs (the BLPs located at the edges are excluded because of the edge effect). The measured average emissivities are 0.4189 and 0.3073 for the op-BLP and cp-BLP arrays, respectively. These experimental measurements agree well with simulation results, 0.449 and 0.301, which are obtained by integrating simulated spectral-directional emissivity ε_{λ,θ} (FIGS. 34E-34F) for both arrays, respectively (see Materials and Methods). The spectral contrast in infrared emissivity for both arrays can also be revealed by the Fourier transform infrared measurements (see FIG. 32B).

Notably, the interstices between neighboring BLPs in both arrays show high emissivities (˜0.5) because they also act as optical cavities enhancing the thermal radiation from the substrate in the interstices, where the Ni coating may not be conformal and, thus, the Si substrate may be partially exposed (see Materials and Methods for the specification of the Si substrate). Such a high background emissivity compromises the emissivity contrast between the two types of BLPs, when estimated at the array level as described above. Here, by calculating the average local emissivities within arbitrarily selected regions containing only individual BLPs (insets of FIGS. 34C-34D), the emissivities of single op-BLPs and cp-BLPs are estimated to be 0.3329 and 0.1329, respectively, which gives rise to an emissivity contrast ratio of approximately 2.5:1. In comparison, the optical images (shown in FIGS. 35A-35B) of the two arrays were analyzed via the quantitative color pattern analysis method (33), which showed well-matched pattern energy distributions (FIG. 35C), indicating the visual indistinguishability of the two arrays to human eyes at visible wavelengths.

Experimental demonstration of visible camouflage and infrared display: The BLP twins represent a pair of binary states under infrared imaging systems due to their emissivity contrast, whereas their nearly identical visible scattering behaviors render them almost indistinguishable to human eyes. Such a wavelength-dependent distinguishability lays the foundation for their camouflage and displays functionalities in the visible and infrared ranges, respectively. The study optimized the design of BLPs by studying the influence of the pore shape and size on the proposed camouflage and display functions. Considering the naturally occurring hexagonal and pentagonal open pores found in leafhopper-produced brochosomes (inset of FIG. 28A), the study designed the BLP arrays composed of op-BLPs and cp-BLPs with polygonal pores in addition to the round ones, as shown in FIG. 36A-a for the particle morphology map and FIG. 36A-b for the SEM images. The array was then examined under both an optical microscope (FIG. 36A-c) and an infrared microscope (FIG. 36A-d) at the same magnification. These observations indicate that variations in pore shape have a minimal impact on their performance. On the basis of the circular-pore design, the study fabricated another array incorporating BLPs with varying pore sizes (FIG. 36B). It was found that increasing pore diameter enhances the infrared emissivity contrast between the two pixels. However, increasing pore diameter simultaneously reduces the visual concealment between the op-BLPs and cp-BLPs.

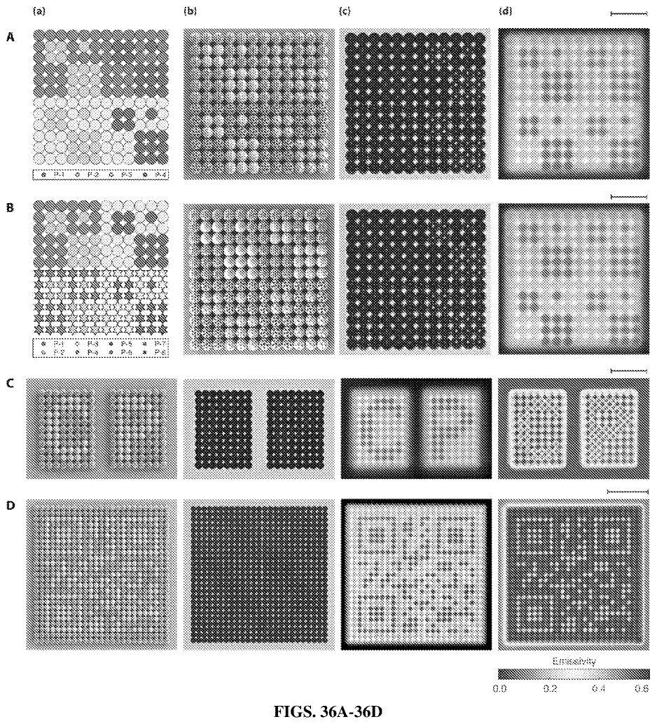

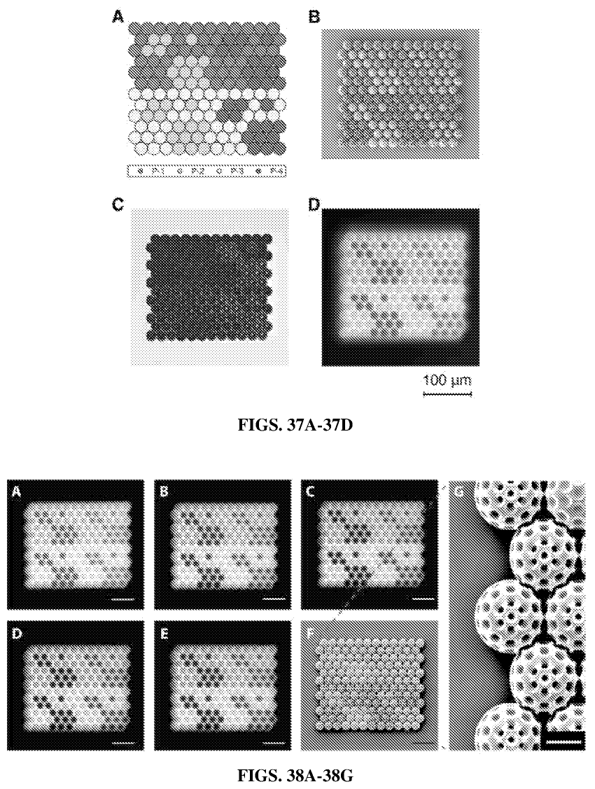

Using the optimized BLPs pair (D=20 μm and d=3.7 μm, round pores, as those in the top left quadrant of the array shown in FIG. 36A), the study demonstrated the pixel-by-pixel camouflage and display functions. FIG. 36C-a shows an SEM image of two BLP arrays, where the study patterned the letters “C” and “P” using the cp-BLPs within the background formed by op-BLPs. The square-packed 20-μm-diameter BLP pixels result in an effective pixel density of 1270 pixel per inch, which is more than five times denser than typical micro-light-emitting diode displays used in smart devices (34), and the BLPs can also be closely packed into a hexagonal lattice for an even greater pixel density (see FIGS. 37A-37D). FIG. 36C-b demonstrates the visible camouflage effect as observed through an optical microscope with a ×20 magnification objective. In this view, the two types of BLPs are indistinguishable, causing the patterns to blend into the background. However, the emissivity difference between the two types of BLPs offers a pronounced contrast to display the hidden patterns in the infrared range, as shown in FIG. 36C-c, which is captured at the same magnification but with an infrared microscope. FIG. 36C-d shows the calculated spatial distribution of emissivity from FIG. 36C-c, where the typical emissivities of each individual op-BLPs and cp-BLPs are approximately 0.35 and 0.15, further verifying the theoretical contrast ratio of around 2.5:1. The thermal stability analysis (see FIGS. 38A-38G) also indicates that the BLP twins enable applications in a temperature range from 50° to 110° C. Furthermore, because of the highly symmetrical arrangement of pores on the BLP surfaces, the infrared emission contrast between the two types of pixels can be maintained even when viewed from different angles. As shown in FIGS. 39A-39E, the C and P patterns remain discernable under infrared microscopes when tilted by a small angle (˜6° achieved by the experimental setup), thus accommodating angular misalignments during the view process. Note that the maximum viewing angle is not limited by the BLPs but rather the focal depth of the infrared microscope. The study further quantified the camouflage and display capabilities of the BLPs by counting the pixel fractions at different brightness level (see FIGS. 33A-33F) based on the method in (35). This analysis revealed that the BLPs preserve a certain degree of camouflage ability even under visible-range dark-field imaging systems.

The study extended the application of BLPs by crafting a BLP array patterned into a quick-response (QR) code (version 1, ECC level L) containing the web address of Carnegie Mellon University, where the cp-BLPs formed the QR code, while the op-BLPs composed the background, as shown in FIG. 36D. The dimension of the QR code is 21 pixel by 21 pixel with a 2-pixel margin on each sides, resulting in a physical size of 0.5 mm by 0.5 mm. Compared with other nano/microstructure-based QR codes, the pixel size and overall QR code dimensions are much smaller than those based on photonic crystals (36, 37) and are comparable to those derived from imprinted polyvinyl alcohol nanostructures (38). This is particularly notable considering that the QR code is designed to function at a longer wavelength. The QR code remains effectively camouflaged during visible-range scanning, as demonstrated in the visible optical image shown in FIG. 36D-b. Conversely, the infrared images of the BLP pixel array (FIG. 36D-c) and calculated emissivity (FIG. 36D-d) clearly display the encrypted QR code, thus allowing rapid scanning using common QR code scanning applications on smart devices. In practice, slightly blurring the infrared images of the BLP QR code, either by defocusing the infrared microscope or by applying Gaussian filters (39, 40), can mitigate the local emissivity variations within single BLPs. This approach can better reveal the binary digits akin to traditional QR codes, making the BLP QR code easier to scan (see FIGS. 40A-40B).

Thermal stability of 3D-printed brochosome-like pixel arrays: The study performed the thermal stability analysis based on the sample shown in FIGS. 37A-37D (see FIGS. 37A-37D for sample specification, the BLPs in the top-left quadrant are those used in the demonstrations showing the letter ‘C’ and ‘P’, and the QR code). FIGS. 38A-38E show the infrared images of the sample captured at different temperature ranging from 50° C. to 110° C. The contrast between open-pore BLPs and close-pore BLPs increases slightly when the temperature is increased from 50° C. (FIG. 38A) to 80° C. (FIG. 38B) but remains almost unchanged afterwards. The SEM images shown in FIGS. 38F-38G, indicate that the BLPs maintain their shapes after being baked at 110° C. for around 30 minutes. Although the study was not able to perform infrared measurement of the sample at a temperature above 110° C. due to the limitation of the thermal mapping system, it is noted that the degradation of the 3D-printed scaffold made of photoresist IP-DIP, which starts to decompose at a temperature above 320° C., could be one possible factor causing the failure of BLPs at higher temperatures.

### Discussion

To summarize, inspired by leafhopper-produced brochosomes, the study created a pair of BLP twins with either open pores or closed pores for microscale thermal signature control. On the basis of the unique emissive and scattering properties of the BLP twins, the study developed a pixel-by-pixel approach for spatial thermal signature control and demonstrated a dual effect of visible camouflage and infrared display via thermal excitation. The BLP-based camouflage effect under visible-range imaging systems arises from their similar visible scattering behaviors, while the high emissivity contrast (2.5:1) between the two types of BLPs enables the thermal display of the concealed information by infrared imaging systems. Although it is well known that the shorter wavelength provides a finer spatial resolution based on the Rayleigh criterion, the study designed a microscopic structure pair to be distinguishable in the infrared range but indistinguishable in the visible range. Using the BLP twins as the fundamental building blocks, this pixel-by-pixel approach allows for systemic and scalable control of thermal signatures, which paves the way for various optical security applications, such as anticounterfeiting and encryption.

The following patents, applications and publications as listed below and throughout this document are hereby incorporated by reference in their entirety herein.

### REFERENCE LIST FOR EXAMPLE 4

1. P. Vukusic, J. R. Sambles, Photonic structures in biology. Nature 424, 852-855 (2003).
2. P. B. Clapham, M. C. Hutley, Reduction of lens reflexion by the “Moth Eye” principle. Nature 244, 281-282 (1973).
3. J. Aizenberg et al., Calcitic microlenses as part of the photoreceptor system in brittlestars. Nature 412, 819-822 (2001).
4. V. C. Sundar et al., Fibre-optical features of a glass sponge. Nature 424, 899-900 (2003).
5. M. Kolle et al., Mimicking the colourful wing scale structure of the Papilio blumei butterfly. Nat. Nanotechnol. 5, 511-515 (2010).
6. V. Sharma et al., Structural origin of circularly polarized iridescence in jeweled beetles. Science 325, 449-451 (2009).
7. P. Vukusic et al., Brilliant whiteness in ultrathin beetle scales. Science 315, 348-348 (2007).
8. P. Vukusic et al., Quantified interference and diffraction in single Morpho butterfly scales. Proc. R. Soc. B: Biol. Sci. 266, 1403-1411 (1999).
9. M. Burresi et al., Bright-white beetle scales optimise multiplescattering of light. Sci. Rep. 4, 6075 (2014).
10. B. D. Wilts et al., Sparkling feather reflections of a bird-of-paradise explained by finite-difference time-domain modeling. Proc. Natl. Acad. Sci. U.S.A. 111, 4363-4368 (2014).
11. T. L. Williams et al., Dynamic pigmentary and structural coloration within cephalopod chromatophore organs. Nat. Commun. 10, 1004 (2019).
12. J. Teyssier et al., Photonic crystals cause active colour change in chameleons. Nat. Commun. 6, 6368 (2015).
13. H. M. Whitney et al., Floral iridescence, produced by diffractive optics, acts as a cue for animal pollinators. Science 323, 130-133 (2009).
14. K. R. Thomas et al., Function of blue iridescence in tropical understorey plants. J. R. Soc. Interface 7, 1699-1707 (2010).
15. S. Vignolini et al., Pointillist structural color in Pollia fruit. Proc. Natl. Acad. Sci. U.S.A. 109, 15712-15715 (2012).
16. X. Fan et al., Light diffraction by sarcomeres produces iridescence in transmission in the transparent ghost catfish. Proc. Natl. Acad. Sci. U.S.A. 120, e2219300120 (2023).
17. K. Shavit et al., A tunable reflector enabling crustaceans to see but not be seen. Science 379, 695-700 (2023).
18. R. A. Rakitov, Secretory products of the Malpighian tubules of Cicadellidae (Hemiptera, Membracoidea): An ultrastructural study. Int. J. Insect Morphol. Embryol. 28, 179-193 (1999).
19. G. Tulloch, J. Shapiro, Brochosomes and leafhoppers. Science 120, 232-232 (1954).
20. M. F. Day, M. Briggs, The origin and structure of brochosomes. J. Ultrastruct. Res. 2, 239-244 (1958).
21. M. A. Mayse, Observations on the occurrence of chalky deposits on forewings of Oncometopia orbona (F) (Homoptera: Cicadellidae). J. Ark. Acad. Sci. 35, 84-86 (1981).
22. R. Hix, Egg-laying and brochosome production observed in glassy-winged sharpshooter. Calif. Agric. 55, 19-22 (2001).
23. E. C. Humphrey, I. Dworakowska, The natural history of brochosomes in Yakuza ganunga (Hemiptera, Auchenorrhyncha, Cicadellidae, Typhlocybinae, Erythroneurini). Denisia 4, 433-454 (2002).
24. R. Rakitov, S. N. Gorb, Brochosomes protect leafhoppers (Insecta, Hemiptera, Cicadellidae) from sticky exudates. J. R. Soc. Interface 10, 20130445 (2013).
25. R. Rakitov, S. N. Gorb, Brochosomal coats turn leafhopper (Insecta, Hemiptera, Cicadellidae) integument to superhydrophobic state. Proc. R. Soc. B: Biol. Sci. 280, 20122391 (2013).
26. S. Yang et al., Ultra-antireflective synthetic brochosomes. Nat. Commun. 8, 1285 (2017).
27. C.-W. Lei et al., Leafhopper wing-inspired broadband omnidirectional antireflective embroidered ball-like structure arrays using a nonlithography-based methodology. Langmuir 36, 5296-5302 (2020).
28. Q. Pan et al., 3D brochosomes-like TiO2/WO3/BiVO4 arrays as photoanode for photoelectrochemical hydrogen production. Small 15, 1900924 (2019).
29. W. Zhao et al., Synergistic plasmon resonance coupling and light capture in ordered nanoarrays as ultrasensitive and reproducible SERS substrates. Nanoscale 12, 18056-18066 (2020).
30. Y. Si et al., Hierarchical macro-mesoporous polymeric carbon nitride microspheres with narrow bandgap for enhanced photocatalytic hydrogen production. Adv. Mater. Interfaces 5, 1801241 (2018).
31. Y. Si et al., Synthesis of biomimetic brochosome-shaped microspheres via droplets assembly strategy. Chem. Mater. 34, 7271-7279 (2022).
32. L. Wang et al., Synthetic brochosomes: Design, synthesis, and applications. Nano Res. 17, 734-742 (2024).
33. G. Mie, Beiträge zur optik trüber medien, speziell kolloidaler metallösungen. Ann. Phys. 330, 377-445 (1908).
34. G. Tulloch et al., The occurrence of ultramicroscopic bodies with leafhoppers and mosquitoes. Bull. Brooklyn Entomol. Soc. 47, 41-42 (1952).
35. X. Fan et al., Light scattering and surface plasmons on small spherical particles. Light Sci. Appl. 3, e179 (2014).
36. P. Spinelli et al., Broadband omnidirectional antireflection coating based on subwavelength surface Mie resonators. Nat. Commun. 3, 692 (2012).
37. C. Genet, T. W. Ebbesen, Light in tiny holes. Nature 445, 39-46 (2007).
38. H. A. Bethe, Theory of diffraction by small holes. Phys. Rev. 66, 163-182 (1944).
39. A. Roberts, Electromagnetic theory of diffraction by a circular aperture in a thick, perfectly conducting screen. J. Opt. Soc. Am. A 4, 1970-1983 (1987).
40. F. J. García de Abajo, Light transmission through a single cylindrical hole in a metallic film. Opt. Express 10, 1475-1484 (2002).
41. F. J. Garcia-Vidal et al., Light passing through subwavelength apertures. Rev. Mod. Phys. 82, 729-787 (2010).
42. T. H. Goldsmith, What birds see. Sci. Am. 295, 68-75 (2006).
43. C. Katti et al., The diversity and adaptive evolution of visual photopigments in reptiles. Front. Ecol. Evol. 7, 352 (2019).
44. D. E. Azofeifa et al., Optical properties of chitin and chitosan biopolymers with application to structural color analysis. Opt. Mater. 35, 175-183 (2012).
45. G. Zhang et al., Cicada wings: A stamp from nature for nanoimprint lithography. Small 2, 1440-1443 (2006).
46. W. H. Miller et al., The optics of insect compound eyes. Science 162, 760-767 (1968).
47. R. A. Raktov, Post-moulting behaviour associated with Malpighian tubule secretions in leafhoppers and treehoppers (Auchenorrhyncha: Membracoidea). Eur. J. Entomol. 93, 167-184 (1996).
48. T. H. Goldsmith, B. K. Butler, The roles of receptor noise and cone oil droplets in the photopic spectral sensitivity of the budgerigar, Melopsittacus undulatus. J. Comp. Physiol. A 189, 135-142 (2003).
49. M. C. Stoddard et al., Wild hummingbirds discriminate nonspectral colors. Proc. Natl. Acad. Sci. U.S.A. 117, 15112-15122 (2020).
50. S. Jacquemoud, S. Ustin, “Leaf optical properties in different wavelength domains” in Leaf Optical Properties, S. Jacquemoud, S. Ustin, Eds. (Cambridge Univ. Press, Cambridge, 2019), chap. 5, pp. 124-169.
51. E. D. Palik, Handbook of Optical Constants of Solids (Academic Press, 1985).
52. R. Rakitov, S. N. Gorb, Brochosomal coats turn leafhopper (Insecta, Hemiptera, Cicadellidae) integument to superhydrophobic state. Proc. R. Soc. B: Biol. Sci. 280, 20122391 (2013).
53. R. A. Rakitov, Secretory products of the Malpighian tubules of Cicadellidae (Hemiptera, Membracoidea): an ultrastructural study. Int. J. Insect Morphol. Embryol. 28, 179-193 (1999).
54. C. Genet, T. W. Ebbesen, Light in tiny holes. Nature 445, 39-46 (2007).
55. H. A. Bethe, Theory of diffraction by small holes. Phys. Rev. 66, 163-182 (1944).
56. A. Roberts, Electromagnetic theory of diffraction by a circular aperture in a thick, perfectly conducting screen. J. Opt. Soc. Am. A 4, 1970-1983 (1987).
57. F. J. García de Abajo, Light transmission through a single cylindrical hole in a metallic film. Opt. Express 10, 1475-1484 (2002).
58. F. J. Garcia-Vidal, L. Martin-Moreno, T. W. Ebbesen, L. Kuipers, Light passing through subwavelength apertures. Rev. Mod. Phys. 82, 729-787 (2010).
59. A. J. Cox, A. J. DeWeerd, J. Linden, An experiment to measure Mie and Rayleigh total scattering cross sections. Am. J. Phys. 70, 620-625 (2002).
60. A. Yoshida, Antireflection of the butterfly and moth wings through microstructure. Forma 17, 75-89 (2002).

### REFERENCE LIST FOR EXAMPLE 5

1. J. Xu et al., Broadband directional control of thermal emission. Science 372, 393-397 (2021).
2. S. Fan, Thermal photonics and energy applications. Joule 1, 264-273 (2017).
3. P. N. Dyachenko et al., Controlling thermal emission with refractory epsilon-near-zero metamaterials via topological transitions. Nat. Commun. 7, 11809 (2016).
4. L. P. Wang, Z. M. Zhang, Wavelength-selective and diffuse emitter enhanced by magnetic polaritons for thermophotovoltaics. Appl. Phys. Lett. 100, 63902 (2012).
5. X. Dang et al., Tunable localized surface plasmon-enabled broadband light-harvesting enhancement for high-efficiency panchromatic dye-sensitized solar cells. Nano Lett. 13, 637-642 (2013).
6. S. Molesky, Z. Jacob, Ideal near-field thermophotovoltaic cells. Phys. Rev. B 91, 205435 (2015).
7. B. Zhao et al., Thermophotovoltaic emitters based on a two-dimensional grating/thin-film nanostructure. Int. J. Heat Mass Transf. 67, 637-645 (2013).
8. E. Rephaeli et al., Ultrabroadband photonic structures to achieve high-performance daytime radiative cooling. Nano Lett. 13, 1457-1461 (2013).
9. T. Li et al., A radiative cooling structural material. Science 364, 760-763 (2019).
10. A. P. Raman et al., Passive radiative cooling below ambient air temperature under direct sunlight. Nature 515, 540-544 (2014).
11. J. Yun et al., Optimally designed multimaterial microparticle-polymer composite paints for passive daytime radiative cooling. ACS Photonics 10, 2608-2617 (2023).
12. X. H. Li et al., Broadband light management with thermochromic hydrogel microparticles for smart windows. Joule 3, 290-302 (2019).
13. R. Hu et al., encrypted thermal printing with regionalization transformation. Adv. Mater. 31, e1807849 (2019).
14. X. Xie et al., Plasmonic metasurfaces for simultaneous thermal infrared invisibility and holographic illusion. Adv. Funct. Mater. 28, 1706673 (2018).
15. G. Cao et al., infrared metasurface-enabled compact polarization nanodevices. Mater. Today 50, 499-515 (2021).
16. J. Kim et al., Scalable manufacturing of high-index atomic layer-polymer hybrid metasurfaces for metaphotonics in the visible. Nat. Mater. 22, 474-481 (2023).
17. C. Kim et al., Laser-induced tuning and spatial control of the emissivity of phase-changing Ge2Sb2te5 emitter for thermal camouflage. Adv. Mater. Technol. 7,2101349 (2022).
18. Z. Xu et al., Spatially resolved dynamically reconfigurable multilevel control of thermal emission. Laser Photonics Rev. 14, 1900162 (2020).
19. Z. J. Coppens, J. G. Valentine, Spatial and temporal modulation of thermal emission. Adv. Mater. 29, 1701275 (2017).
20. D. Franklin et al., Covert infrared image encoding through imprinted plasmonic cavities. Light Sci. Appl. 7, 93 (2018).
21. O. Salihoglu et al., Graphene-based adaptive thermal camouflage. Nano Lett. 18, 4541-4548 (2018).
22. G. S. Tulloch, J. E. Shapiro, Brochosomes and leafhoppers. Science 120, 232-232 (1954).
23. R. Rakitov, S. N. Gorb, Brochosomes protect leafhoppers (insecta, hemiptera, cicadellidae) from sticky exudates. J. R. Soc. Interface 10, 20130445 (2013).
24. S. Yang et al., Ultra-antireflective synthetic brochosomes. Nat. Commun. 8, 1285 (2017).
25. L. Wang et al., Synthetic brochosomes: design, synthesis, and applications. Nano Res. 17, 734-742 (2024).
26. M. Stevens, S. Merilaita, Animal camouflage: current issues and new perspectives. Philos. Trans. R Soc. Lond. B Biol. Sci. 364, 423-427 (2009).
27. S. Merilaita, J. Lind, Background-matching and disruptive coloration, and the evolution of cryptic coloration. Proc. Biol. Sci. 272, 665-670 (2005).
28. K. Vynck et al., The visual appearances of disordered optical metasurfaces. Nat. Mater. 21, 1035-1041 (2022).
29. M. Pharr et al., Physically Based Rendering (Morgan Kaufmann, ed. 3, 2017).
30. T. Bergman et al., Fundamentals of Heat and Mass Transfer (John Wiley & Sons inc., ed. 7, 2011).
31. R. A. Rakitov, Secretory products of the Malpighian tubules of cicadellidae (hemiptera, Membracoidea): An ultrastructural study. Int. J. Insect Morphol. Embryol. 28, 179-193 (1999).
32. J. Stam, Diffraction Shaders, in Proceedings of the 26th Annual Conference on Computer Graphics and Interactive Techniques—SIGGRAPH '99 (AcM Press, 1999), p. 101-110.
33. C. P. van den Berg et al., Quantitative colour pattern analysis (QcPA): A comprehensive framework for the analysis of colour patterns in nature. Methods Ecol. Evol. 11, 316-332 (2020)
34. X. Zhou et al., Growth, transfer printing and colour conversion techniques towards full-colour micro-Led display. Prog. Quantum. Electron. 71, 100263 (2020).
35. S. A. Morin et al., Camouflage and display for soft machines. Science 337, 828-832 (2012).
36. Y. Fu et al., Reversible photochromic photonic crystal device with dual structural colors. ACS Appl. Mater. Interfaces 14, 29070-29076 (2022).
37. M. Abdolahi et al., Structural colour QR codes for multichannel information storage with enhanced optical security and life expectancy. Nanotechnology 30, 405301(2019).
38. B. Ko et al., tunable metasurfaces via the humidity responsive swelling of single-step imprinted polyvinyl alcohol nanostructures. Nat. Commun. 13, 6256 (2022).
39. A. E. Savakis, H. J. Trussell, On the accuracy of PSF representation in image restoration. IEEE Trans. Image Process. 2, 252-259 (1993).
40. Y.-Q. Liu et al., Estimating generalized Gaussian blur kernels for out-of-focus image deblurring. IEEE Trans. Circuits Syst. Video Technol. 31, 829-843(2021).
41. E. D. Palik, Handbook of Optical Constants of Solids (Academic Press, 1985)

What is claimed is:

1. A method of forming a synthetic brochosome, comprising:
irradiating a portion of a photoresist coated onto a substrate with a focused radiation beam or light sheet, wherein the beam or light sheet is moved along a designated pathway within the photoresist to polymerize the portion of the photoresist irradiated by the beam or light sheet; and
removing a portion of the photoresist from the substrate that is not irradiated and not polymerized by the beam or light sheet,
thereby providing a synthetic brochosome.

2. The method of claim 1, wherein the beam or light sheet is moved along a pathway within the photoresist according to predetermined coordinates.

3. The method of claim 1, wherein the beam or light sheet is moved along an x, y, and/or z direction relative to the position of the photoresist.

4. The method of claim 1, wherein the position of the photoresist is moved along an x, y, and/or z direction relative to the beam or light sheet.

5. The method of claim 1, wherein the photoresist comprises IP-DIP, IP-S, IP-PDMS, IP-n162, IP-Visio, IP-Q, IP-G, IP-L, epoxy-based SU-8, hybrid sol-gel Ormocer or Ormocomp, or any combinations thereof.

6. The method of claim 1, wherein the substrate comprises silicon, glass, quartz, indium tin oxide coated glass (ITO-glass), metals such as stainless steel, carbon steel, aluminum, titanium, nickel alloy, copper, brass, bronze; plastics such as polycarbonate, poly(methyl methacrylate); or other infrared transparent materials such as calcium fluoride, germanium, zinc selenide, barium fluoride, sapphire, gallium arsenide, BK7 schott glass; or any combination thereof.

7. The method of claim 1, further comprising coating the synthetic brochosome with a second material using electron beam evaporation or sputtering methods, wherein the second material comprises nickel, gold, silver, platinum, aluminum, chromium, cobalt, copper, germanium, iron, molybdenum, palladium, rhenium, titanium, tungsten. alumina, silicon dioxide, titanium dioxide, carbon, parylene, or any combination thereof.

8. A synthetic brochosome comprising a photoresist having a conductive coating.

9. The synthetic brochosome of claim 8, wherein the photoresist comprises IP-DIP, IP-S, IP-PDMS, IP-n162, IP-Visio, IP-Q, IP-G, IP-L, epoxy-based SU-8, hybrid sol-gel Ormocer or Ormocomp, or any combinations thereof.

10. The synthetic brochosome of claim 8, wherein the conductive coating comprises nickel, gold, silver, platinum, aluminum, chromium, cobalt, copper, germanium, iron, molybdenum, palladium, rhenium, titanium, and tungsten, silicon dioxide, titanium dioxide, carbon, parylene, or any combination thereof.

11. The synthetic brochosome of claim 8, wherein the synthetic brochosome has a particle diameter of from about 5 μm to about 100 μm.

12. The synthetic brochosome of claim 8, wherein the synthetic brochosome has a through-hole size of from about 1 μm to about 30 μm.

13. The synthetic brochosome of claim 8, wherein the synthetic brochosome has a through-hole wall thickness of from about 1 μm to about 13 μm.

14. The synthetic brochosome of claim 8, wherein the synthetic brochosome has a porosity of from about 50% to 99%.

15. The synthetic brochosome of claim 8, wherein the synthetic brochosome has a shell wall thickness of from about 1 μm to about 20 μm.

16. The synthetic brochosome of claim 8, wherein the synthetic brochosome comprises through-holes, indentations, surface cavities, or closed-pores.

17. The synthetic brochosome of claim 8, wherein the synthetic brochosomes comprises through-holes, or open-pores that are interconnected by a hollow core.

18. The synthetic brochosome of claim 8, wherein the through-holes of the synthetic brochosome are arranged in a crystal or quasiperiodic-crystal or random pattern.

19. A coated substrate comprising a coating of the synthetic brochosome of claim 8 disposed on a substrate.

20. The coated substrate of claim 19, wherein the synthetic brochosomes are arranged in hexagonal close-packing, square close-packing, or other arbitrary packing.

21. The coated substrate of claim 19, wherein the inter-particle spacing between individual synthetic brochosomes is smaller or equal to the characteristic diameter of the through-holes or cavities of the brochosomes.

22. The coated substrate of claim 19, wherein the coating is an antireflective coating.

23. The coated substrate of claim 19, wherein the coating has a reflectance of from about 5% to about 20% at a wavelength in a range from about 2.5 μm to about 25 μm.

24. The coated substrate of claim 19, wherein the coating comprises of a mixture of synthetic brochosomes with through-holes and synthetic brochosomes with closed-pores.

25. The coated substrate of claim 19, wherein the coated substrate is used for information encryption at a wavelength in a range from about 2.5 μm to about 25 μm.
